(19) United States
(12) Patent Application Publication
(10) Pub. No.: US 2023/0411529 A1
(43) Pub. Date: Dec. 21, 2023

(54) SEMICONDUCTOR DEVICE AND METHOD FOR FABRICATING THE SAME

(71) Applicant: Samsung Electronics Co., Ltd., Suwon-si (KR)

(72) Inventors: Hyo Jin Kim, Suwon-si (KR); Sang Moon Lee, Suwon-si (KR); Jin Bum Kim, Suwon-si (KR); Yong Jun Nam, Suwon-si (KR)

(21) Appl. No.: 18/160,297

(22) Filed: Jan. 26, 2023

(30) Foreign Application Priority Data
Jun. 17, 2022 (KR) 10-2022-0073910

(51) Int. Cl. H01L 29/786; H01L 29/06; H01L 29/08; H01L 21/8234

(52) U.S. Cl. CPC H01L 29/78672; H01L 29/78696; H01L 29/0673; H01L 29/0847; H01L 21/823412; H01L 21/823418

(57) ABSTRACT

A semiconductor device includes a lower pattern extending in a first direction, a first blocking structure which is on the lower pattern and includes at least one first blocking film comprising an oxygen-doped crystalline silicon film, a source/drain pattern on the first blocking structure, and a gate structure which extends in a second direction on the lower pattern and includes a gate electrode and a gate insulating film. Related fabrication methods are also discussed.

### CROSS-REFERENCE TO RELATED APPLICATION

This application claims priority from Korean Patent Application No. 10-2022-0073910 filed on Jun. 17, 2022 in the Korean Intellectual Property Office, and all the benefits accruing therefrom under 35 U.S.C. 119, the contents of which in its entirety are herein incorporated by reference.

### FIELD

The present disclosure relates to a semiconductor device and a method for fabricating the same.

### BACKGROUND

As one of several scaling technologies for increasing density of semiconductor devices, a multi gate transistor in which a multi-channel active pattern (or a silicon body) having a fin or nanowire shape is formed on a substrate and a gate is formed on a surface of the multi-channel active pattern has been proposed.

Since such a multi gate transistor utilizes a three-dimensional channel, scaling can be more easily accomplished. Even if gate length of the multi gate transistor is not increased, current control capability may be improved. Furthermore, a SCE (short channel effect) in which potential of a channel region is influenced by a drain voltage may be effectively suppressed.

### SUMMARY

Aspects of the present disclosure provide a semiconductor device capable of improving element performance and reliability.

Aspects of the present disclosure also provide a method for fabricating a semiconductor device capable of improving element performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising a lower pattern extending in a first direction; a first blocking structure on the lower pattern and comprising at least one first blocking film, the first blocking film comprising an oxygen-doped crystalline silicon film; a source/drain pattern on the first blocking structure; and a gate structure extending in a second direction on the lower pattern and comprising a gate electrode and a gate insulating film.

According to another aspect of the present disclosure, there is provided a semiconductor device comprising a lower pattern extending in a first direction; a blocking structure on the lower pattern and comprising at least one blocking film, the at least one blocking film comprising an oxygen-doped crystalline silicon film; a plurality of sheet patterns on the blocking structure and arranged in a second direction; a gate structure extending in a third direction on the lower pattern and comprising a gate electrode and a gate insulating film, the gate electrode overlapping the blocking structure in the second direction; and a source/drain pattern that overlaps the blocking structure in the second direction and is connected to the sheet pattern.

According to still another aspect of the present disclosure, there is provided a semiconductor device comprising a lower pattern that extends in a first direction and comprises a blocking structure recess; a blocking structure on the lower pattern and comprising a plurality of blocking films and one or more insertion semiconductor films, the blocking films comprising an oxygen-doped crystalline silicon film, and the insertion semiconductor films comprising a crystalline silicon film having a lower oxygen concentration than the blocking films; a plurality of sheet patterns on the lower pattern and arranged in a second direction; a source/drain pattern connected to the sheet pattern on the blocking structure and comprising n-type dopants; and a gate structure extending in a third direction on the lower pattern and comprising a gate electrode and a gate insulating film.

According to still another aspect of the present disclosure, there is provided a method for fabricating a semiconductor device comprising forming a lower pattern, a blocking structure, and an upper pattern structure on a substrate, the upper pattern structure comprising a plurality of sacrificial patterns and active patterns that are alternately stacked, wherein the blocking structure is between the lower pattern and the upper pattern structure; forming a plurality of dummy gate electrodes on the upper pattern structure; forming a source/drain pattern connected to the active pattern between adjacent ones of the dummy gate electrodes; and forming a sheet pattern connected to the source/drain pattern by removing the sacrificial patterns after forming the source/drain pattern, wherein the blocking structure comprises a blocking film and an insertion semiconductor film that are alternately stacked, the blocking film comprises an oxygen-doped crystalline silicon film, and the insertion semiconductor film comprises a crystalline silicon film having a lower oxygen concentration than the blocking film.

According to still another aspect of the present disclosure, there is provided a method for fabricating a semiconductor device comprising forming a lower pattern and an upper pattern structure on a substrate, the upper pattern structure comprising a plurality of sacrificial patterns and active patterns that are alternately stacked; forming a plurality of dummy gate electrodes on the upper pattern structure; forming a blocking structure recess in the upper pattern structure and the lower pattern between adjacent ones of the dummy gate electrodes, wherein a bottom surface of the blocking structure recess is defined by the lower pattern; forming a blocking structure in a part of the blocking structure recess; forming a source/drain pattern connected to the active pattern on the blocking structure; and forming a sheet pattern connected to the source/drain pattern by removing the sacrificial patterns after forming the source/drain pattern, wherein the blocking structure comprises a blocking film and an insertion semiconductor film that are alternately stacked, the blocking film comprises an oxygen-doped crystalline silicon film, and the insertion semiconductor film comprises a crystalline silicon film having a lower oxygen concentration than the blocking film.

### BRIEF DESCRIPTION OF DRAWINGS

The above and other aspects and features of the present disclosure will become more apparent by describing in detail illustrative embodiments thereof with reference to the attached drawings, in which:

FIG. 1 is a schematic plan view for explaining a semiconductor device according to some embodiments;

FIGS. 2, 3, and 4 are cross-sectional views taken along A-A, B-B and C-C of FIG. 1;

FIGS. 5 and 6 are exemplary enlarged views showing a portion P of FIG. 2;

FIG. 7 is a diagram schematically showing a concentration of oxygen along a SCAN LINE of FIG. 5;

FIGS. 8 and 9 are diagrams for explaining a semiconductor device according to some embodiments, respectively;

FIGS. 10 and 11 are diagrams for explaining a semiconductor device according to some embodiments, respectively;

FIGS. 12, 13, and 14 are diagrams for explaining a semiconductor device according to some embodiments;

FIGS. 15, 16, 17, 18, 19, and 20 are diagrams for explaining a semiconductor device according to some embodiments;

FIGS. 21, 22, 23, 24, and 25 are diagrams for explaining a semiconductor device according to some embodiments;

FIGS. 26, 27, 28, 29, and 30 are diagrams for explaining a semiconductor device according to some embodiments, respectively;

FIGS. 31, 32, 33, and 34 are diagrams for explaining a semiconductor device according to some embodiments;

FIGS. 35 and 36 are diagrams for explaining a semiconductor device according to some embodiments;

FIGS. 37, 38, 39, 40, 41, 42, 43, and 44 are intermediate step diagrams for describing a method for fabricating a semiconductor device according to some embodiments;

FIGS. 45, 46, 47, 48, and 49 are intermediate step diagrams for describing a method for fabricating the semiconductor device according to some embodiments.

### DETAILED DESCRIPTION OF THE EMBODIMENTS

Although drawings of a semiconductor device according to some embodiments show a fin-shaped transistor (FinFET) including a channel region of a fin-shaped pattern shape, and a transistor including a nanowire or a nanosheet as an example, the embodiments are not limited thereto. The technical idea of the present disclosure may apply to transistors based on two-dimensional materials (2D material based FETs) and a heterostructure thereof.

Further, the semiconductor device according to some embodiments may also include a tunneling transistor (tunneling FET) or a three-dimensional (3D) transistor. The semiconductor device according to some embodiments may include a bipolar junction transistor, a laterally diffused metal oxide semiconductor (LDMOS), or the like.

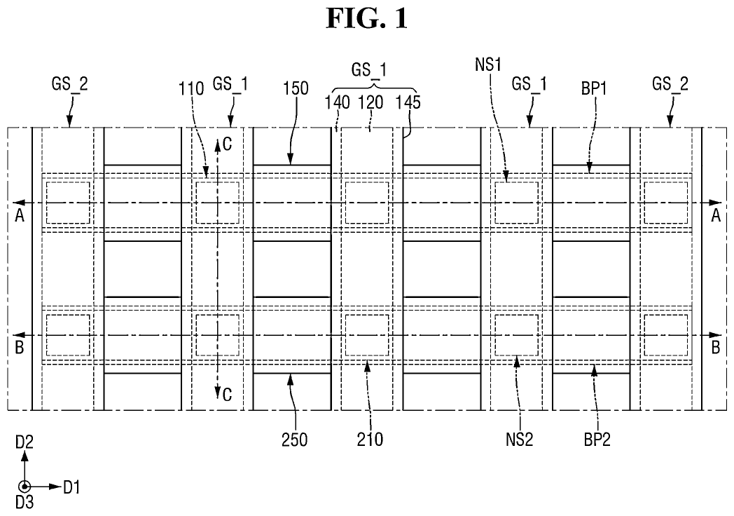

A semiconductor device according to some embodiments will be described with reference to FIGS. 1 to 7

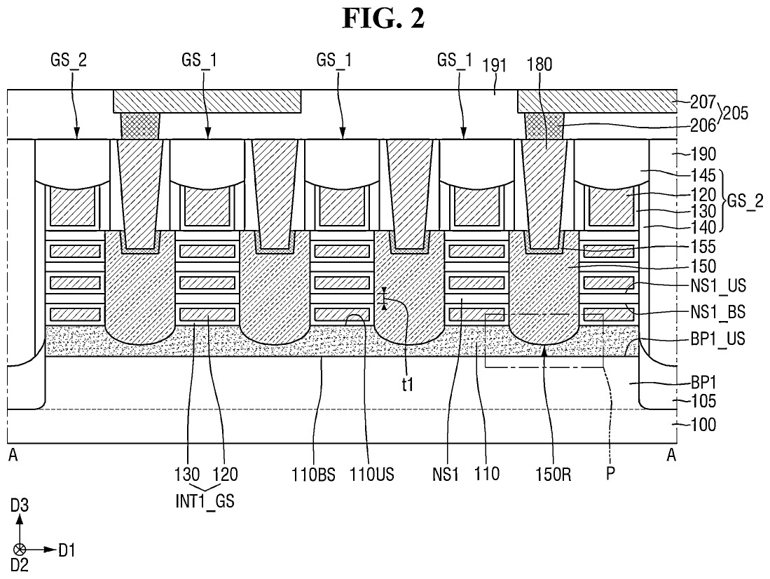

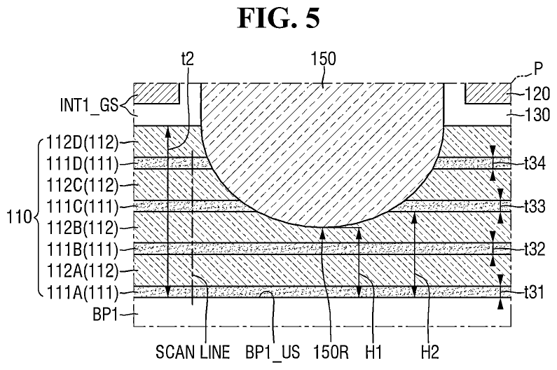

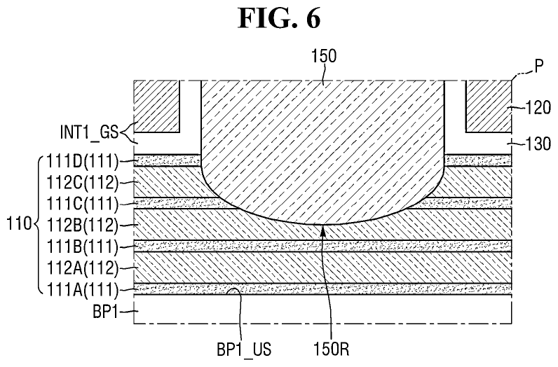

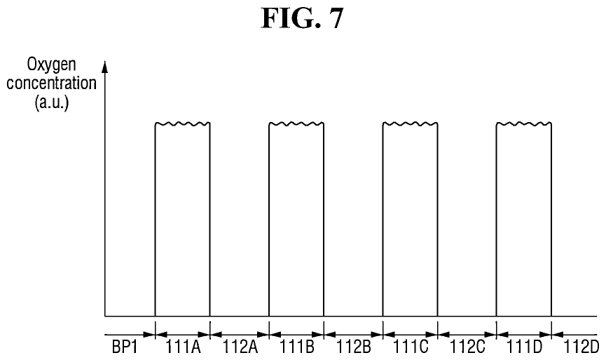

FIG. 1 is a schematic plan view for explaining a semiconductor device according to some embodiments. FIGS. 2 to 4 are cross-sectional views taken along A-A, B-B and C-C of FIG. 1. FIGS. 5 and 6 are example enlarged views showing a portion P of FIG. 2. FIG. 7 is a diagram schematically showing a concentration of oxygen along a SCAN LINE of FIG. 5.

For reference, FIG. 1 is simply shown, except for a gate insulating film 130, interlayer insulating films 190 and 191, a wiring structure 205, and the like.

Referring to FIGS. 1 to 7, a semiconductor device according to some embodiments may include a first lower pattern BP1, a second lower pattern BP2, a first sheet pattern NS1, a second sheet pattern NS2, a first line blocking structure 110, a second line blocking structure 210, a plurality of gate structures GS_1 and GS_2, a first source/drain pattern 150 and a second source/drain pattern 250. The terms “first,” “second,” etc., may be used herein merely to distinguish one element from another.

The substrate 100 may be bulk silicon or silicon-on-insulator (SOI). Alternatively, the substrate 100 may be a silicon substrate, or may include, but not limited to, other materials, for example, silicon germanium, SGOI (silicon germanium on insulator), indium antimonide, lead tellurium compounds, indium arsenic, indium phosphide, gallium arsenide or gallium antimonide.

The first lower pattern BP1 may protrude from the substrate 100 in a third direction D3, which may be different from (e.g., perpendicular to) first and second directions D1 and D2. The first lower pattern BP1 may extend long in the first direction D1. The first lower pattern BP1 includes a long side extending in the first direction D1, and a short side extending in a second direction D2. A terminating end of the first lower pattern BP1 may include the short side of the first lower pattern BP1.

The second lower pattern BP2 may protrude from the substrate 100 in a third direction D3. The second lower pattern BP2 may extend long in the first direction D1. The second lower pattern BP2 may be spaced apart from the first lower pattern BP1 in the second direction D2. A terminating end of the second lower pattern BP2 may include the short side of the second lower pattern BP2.

For example, the first lower pattern BP1 may be disposed in an NMOS formation region. The second lower pattern BP2 may be disposed in a PMOS formation region.

Each of the first lower pattern BP1 and the second lower pattern BP2 may each be formed by etching a part of the substrate 100, and may include an epitaxial layer grown from the substrate 100. The first lower pattern BP1 and the second lower pattern BP2 may each include silicon or germanium, which is an elemental semiconductor material. Also, the first lower pattern BP1 and the second lower pattern BP2 may each include a compound semiconductor, and may include, for example, a group IV-IV compound semiconductor or a group 111-V compound semiconductor.

The group IV-IV compound semiconductor may be, for example, a binary compound or a ternary compound including at least two or more of carbon (C), silicon (Si), germanium (Ge) and tin (Sn), or a compound obtained by doping these elements with a group IV element.

The group 111-V compound semiconductor may be, for example, one of a binary compound, a ternary compound or a quaternary compound formed by combining at least one of aluminum (Al), gallium (Ga) and indium (In) as a group 111 element with one of phosphorus (P), arsenic (As) and antimony (Sb) as a group V element.

A field insulating film 105 may be formed on the substrate 100. The field insulating film 105 may be disposed on the side walls of the first lower pattern BP1. The field insulating film 105 may be disposed on the side walls of the second lower pattern BP2. The field insulating film 105 is not disposed on an upper surface BP1_US of the first lower pattern and an upper surface BP2_US of the second lower pattern.

As an example, the field insulating film 105 may entirely cover the side walls of the first lower pattern BP1 and/or side walls of the second lower pattern BP2. Unlike the shown example, the field insulating film 105 may cover a part of the side walls of the first lower pattern BP1 and a part of the side walls of the second lower pattern BP2. In such a case, a part of the first lower pattern BP1 and/or a part of the second lower pattern BP2 may protrude from an upper surface of the field insulating film 105 in the third direction D3.

The upper surface of the field insulating film 105 may have a concave shape, but is not limited thereto. The field insulating film 105 may include, for example, an oxide film, a nitride film, an oxynitride film or a combination thereof. Although the field insulating film 105 is shown as a single film, this example is only for convenience of explanation and is not limited thereto.

The first line blocking structure 110 is disposed on the first lower pattern BP1. The first line blocking structure 110 is disposed on the upper surface BP1_US of the first lower pattern. The first line blocking structure 110 may extend in the first direction D1 along the upper surface BP1_US of the first lower pattern. The first line blocking structure 110 may come into contact with the upper surface BP1_US of the first lower pattern.

The first line blocking structure 110 includes an upper surface 110US and a lower surface 110BS. The lower surface 110BS of the first line blocking structure faces the upper surface BP1_US of the first lower pattern. The lower surface 110BS of the first line blocking structure may come into contact with (e.g., may be directly on) the upper surface BP1_US of the first lower pattern. The upper surface 110US of the first line blocking structure is a surface that is opposite to the lower surface 110BS of the first line blocking structure in the third direction D3. For example, in FIG. 2, the upper surface BP1_US of the first lower pattern is a contact surface that comes into contact with the lower surface 110BS of the first line blocking structure. When elements are described herein as “directly on” or in “direct contact,” no intervening elements are present.

The second line blocking structure 210 is disposed on the second lower pattern BP2. The second line blocking structure 210 is disposed on the upper surface BP2_US of the second lower pattern. The second line blocking structure 210 may extend in the first direction D1 along the upper surface BP2_US of the second lower pattern. The second line blocking structure 210 may come into contact with the upper surface BP2_US of the second lower pattern. The second line blocking structure 210 is spatially separated from the first line blocking structure 110.

The second line blocking structure 210 includes an upper surface 210US and a lower surface 210BS. The lower surface 210BS of the second line blocking structure faces the upper surface BP2_US of the second lower pattern. The lower surface 210BS of the second line blocking structure may come into contact with (e.g., may be directly on) the upper surface BP2_US of the second lower pattern. The upper surface 210US of the second line blocking structure is a surface that is opposite to the lower surface 210BS of the second line blocking structure in the third direction D3.

Although at least a part of the side walls of the first line blocking structure 110 and at least a part of the side walls of the first line blocking structure 110 are each shown to be covered with the field insulating film 105, the example is not limited thereto.

The first line blocking structure 110 may include at least one line blocking film 111. The first line blocking structure 110 may include a line insertion semiconductor film 112. For example, the number of line insertion semiconductor films 112 may be the same as the number of line blocking films 111. As another example, the number of line insertion semiconductor films 112 may be smaller than the number of line blocking films 111 by one. As yet another example, the number of line insertion semiconductor films 112 may be greater than the number of line blocking films 111 by one.

In the semiconductor device according to some embodiments, the first line blocking structure 110 may include a plurality of line blocking films 111 and at least one (i.e., one or more) line insertion semiconductor films 112. The plurality of line blocking films 111 and line insertion semiconductor film(s) 112 may be alternately stacked on the first lower pattern BP1. The first line blocking structure 110 may have a superlattice structure in which the line blocking films 111 and the line insertion semiconductor films 112 are alternately stacked.

The line blocking film 111 may be an oxygen-doped crystalline silicon film. The line blocking film 111 is in a state in which crystalline silicon film is doped with oxygen. The line insertion semiconductor film 112 may be a crystalline silicon film having a comparatively lower oxygen concentration (and in some embodiments, may be substantially free of oxygen doping). Since the line blocking film 111 and the line insertion semiconductor film 112 are formed using an epitaxial growth method, the line blocking film 111 and the line insertion semiconductor film 112 may be epitaxial patterns. The line blocking film 111 and the line insertion semiconductor film 112 may maintain crystallinity of the first lower pattern BP1.

In FIGS. 5 and 6, the line blocking film 111 may include a plurality of sub-blocking films 111A, 111B, 111C and 111D. Although the line blocking film 111 is shown to include the four sub-blocking films 111A, 111B, 111C and 111D, the example is only for convenience of explanation and is not limited thereto. The line blocking film 111 may include two or three sub-blocking films, or may include five or more sub-blocking films.

The first to fourth sub-blocking films 111A, 111B, 111C and 111D may be sequentially disposed on the first lower pattern BP1. The first to fourth sub-blocking films 111A, 111B, 111C and 111D are spaced apart from each other in the third direction D3.

A first sub-blocking film 111A may be disposed at the lowermost part among the sub-blocking films 111A, 111B, 111C and 111D. For example, the first sub-blocking film 111A may come into contact with the upper surface BP1_US of the first lower pattern. The lower surface 110BS of the first line blocking structure may be the first sub-blocking film 111A.

A fourth sub-blocking film 111D may be disposed on an uppermost part among the sub-blocking films 111A, 111B, 111C and 111D. The second sub-blocking film 111B and the third sub-blocking film 111C are disposed between the first sub-blocking film 111A and the fourth sub-blocking film 111D.

Although a thickness t31 of the first sub-blocking film 111A, a thickness t32 of the second sub-blocking film 111B, a thickness t33 of the third sub-blocking film 111C, and a thickness t34 of the fourth sub-blocking film 111D may be the same, the example is not limited thereto. Each of the thickness t31 of the first sub-blocking film 111A, the thickness t32 of the second sub-blocking film 111B, the thickness t33 of the third sub-blocking film 111C, and the thickness t34 of the fourth sub-blocking film 111D is smaller than a thickness t1 of a first sheet pattern NS1, which will be described below.

In FIG. 7, the concentrations ((/cm³) or at % (atomic percent)) of oxygen included in the first to fourth sub-blocking films 111A, 111B, 111C and 111D may be the same, but is not limited thereto.

In FIG. 5, the line insertion semiconductor film 112 may include first to fourth sub-insertion semiconductor films 112A, 112B, 112C and 112D. A first sub-insertion semiconductor film 112A, a second sub-insertion semiconductor film 112B and a third sub-insertion semiconductor film 112C are disposed between the first to fourth sub-blocking films 111A, 11B, 111C and 111D. A fourth sub-insertion semiconductor film 112D is disposed on the fourth sub-blocking film 111D.

In FIGS. 2 and 5, the upper surface 110US of the first line blocking structure may be the fourth sub-insertion semiconductor film 112D. For example, the fourth sub-insertion semiconductor film 112D may come into contact with a first inner gate structure INT1_GS, which will be described below. In the semiconductor device according to some embodiments, the upper surface 110US of the first line blocking structure may be an interfacial film between the fourth sub-insertion semiconductor film 112D and the first inner gate structure INT1_GS.

In FIG. 6, the line insertion semiconductor film 112 may include first to third sub-insertion semiconductor films 112A, 112B and 112C. No sub-insertion semiconductor film is disposed on the fourth sub-blocking film 111D. In FIGS. 2 and 6, the upper surface 110US of the first line blocking structure may be the fourth sub-blocking film 111D. For example, the fourth sub-blocking film 111D may come into contact with a first inner gate structure INT1_GS, which will be described below.

Unlike the example shown in FIGS. 5 and 6, an additional line insertion semiconductor film 112 may be disposed between the first sub-blocking film 111A and the first lower pattern BP1. In this case, the lower surface 110BS of the first line blocking structure may be a line insertion semiconductor film disposed between the first sub-blocking film 111A and the first lower pattern BP1.

The thickness of the pair of line blocking films 111 and line insertion semiconductor film 112 may be, for example, 10 Å to 100 Å. For example, the sum of the thickness of the first sub-blocking film 111A and the thickness of the first sub-insertion semiconductor film 112A, which are adjacent to each other, may be, for example, 10 Å to 100 Å.

The second line blocking structure 210 has the same structure as the first line blocking structure 110. Since the description of the second line blocking structure 210 is substantially the same as the description of the first line blocking structure 110, the description will not be repeated.

A plurality of first sheet patterns NS1 may be disposed on the first line blocking structure 110. The plurality of first sheet patterns NS1 may overlap the first line blocking structures 110 in the third direction D3.

The plurality of first sheet patterns NS1 are arranged on the first line blocking structure 110 in the third direction D3. Each first sheet pattern NS1 is spaced apart in the third direction D3. The first sheet pattern NS1 includes an upper surface NS1_US and a lower surface NS1_BS that are opposite to each other in the third direction D3.

A second sheet pattern NS2 may be disposed on the second line blocking structure 210. The second sheet pattern NS2 may overlap the second line blocking structure 210 in the third direction D3.

The plurality of second sheet patterns NS2 are arranged on the second line blocking structure 210 in the third direction D3. Each second sheet pattern NS2 is spaced apart in the third direction D3. The second sheet pattern NS2 includes an upper surface NS2_US and a lower surface NS2_BS that are opposite to each other in the third direction D3.

For example, the first sheet pattern NS1 may be included in a channel region of NMOS. The second channel pattern NS2 may be included in a channel region of PMOS.

Although three first sheet patterns NS1 and three second sheet patterns NS2 are shown as being disposed in the third direction D3, the example is only for convenience of explanation and is not limited thereto. Although each first sheet pattern NS1 has the same width in the first direction D1, the example is not limited thereto. Although the widths of each of the second sheet patterns NS2 in the first direction D1 are shown to be the same, the example is not limited thereto.

The first sheet pattern NS1 and the second sheet pattern NS2 may each include one of silicon or germanium which is an elemental semiconductor material, a group IV-IV compound semiconductor, or a group 111-V compound semiconductor. Each first sheet pattern NS1 may include the same material as the first lower pattern BP1, or may include a different material from the first lower pattern BP1. Each second sheet pattern NS2 may include the same material as the second lower pattern BP2, or may include a different material from the second lower pattern BP2.

In the semiconductor device according to some embodiments, the first lower pattern BP1 and the second lower pattern BP2 may each be a silicon lower pattern including silicon. The first sheet pattern NS1 and the second sheet pattern NS2 may each be a silicon sheet pattern including silicon.

The width of the first sheet pattern NS1 in the second direction D2 may increase or decrease in proportion to the width of the upper surface BP1_US of the first lower pattern in the second direction D2. The width of the second sheet pattern NS2 in the second direction D2 may increase or decrease in proportion to the width of the upper surface BP2_US of the second lower pattern in the second direction D2.

Although an example is shown in which the first sheet patterns NS1 stacked in the third direction D3 have the same width in the second direction D2, and the second sheet patterns NS2 stacked in the third direction D3 have the same width in the second direction (D2), the example is only for convenience of explanation and is not limited thereto. Unlike the shown example, the width in the second direction D2 of the first sheet patterns NS1 stacked in the third direction D3 may decrease, as it goes away from (i.e., with distance from)_the first lower pattern BP1. The above description may likewise apply to the second sheet pattern NS2.

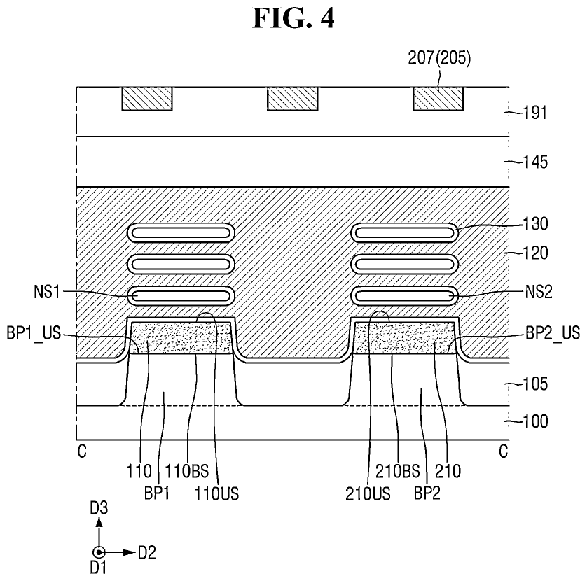

Although FIGS. 1 and 4 show that the width of the first lower pattern BP1 in the second direction D2 is the same as the width of the second lower pattern BP2 in the second direction D2, the example is not limited thereto. For reference, the width of the first lower pattern BP1 in the second direction D2 may be a width of the upper surface BP1_US of the first lower pattern in the second direction D2.

As an example, the first lower pattern BP1 may be disposed directly adjacent to the second lower pattern BP2 in the second direction D2. Alternatively, no additional lower pattern and channel pattern may be disposed between the first lower pattern BP1 and the second lower pattern BP2.

Unlike the shown example, as another example, the second lower pattern BP2 may be disposed in a region spatially spaced apart from the first lower pattern BP1. In this case, unlike the first lower pattern BP1, the second lower pattern BP2 may extend long in the first direction D1.

A plurality of gate structures GS_1 and GS_2 may be disposed on the substrate 100. Each of the gate structures GS_1 and GS_2 may extend in the second direction D2. The gate structures GS_1 and GS_2 may be spaced apart in the first direction D1. The gate structures GS_1 and GS_2 may be adjacent to each other in the first direction D1.

The gate structures GS_1 and GS_2 are disposed on the first lower pattern BP1 and the second lower pattern BP2. The gate structures GS_1 and GS_2 (extending in the second direction D2) may intersect the first lower pattern BP1 and the second lower pattern BP2 (extending in the first direction D1). The gate structures GS_1 and GS_2 may include, for example, a gate electrode 120, a gate insulating film 130, a gate spacer 140, and a gate capping pattern 145.

Although each of the gate structures GS_1 and GS_2 are shown as being disposed over the first lower pattern BP1 and the second lower pattern BP2, the example is only for convenience of explanation and is not limited thereto.

As an example, a part of the gate structures GS_1 and GS_2 are separated into two portions and may be disposed on the first lower pattern BP1 and the second lower pattern BP2. That is, the first gate structure on the first lower pattern BP1 may be separated from the second gate structure on the second lower pattern BP2 in the second direction D2. In such a case, the first gate electrode and the first gate insulating film included in the first gate structure may be separated from the second gate electrode and the second gate insulating film included in the second gate structure.

Unlike the shown example, as another example, when the second lower pattern BP2 is disposed in a region spatially spaced apart from the first lower pattern BP1, the first gate structure on the first lower pattern BP1 may be spatially separated from the second gate structure on the second lower pattern BP2. Also in this case, the first gate electrode and the first gate insulating film included in the first gate structure are separated from the second gate electrode and the second gate insulating film included in the second gate structure.

The plurality of gate structures GS_1 and GS_2 may include a normal gate structure GS_1 and an edge gate structure GS_2. The edge gate structure GS_2 may be disposed at the terminating end of the first lower pattern BP1 and/or the terminating end of the second lower pattern BP2. The normal gate structure GS_1 is disposed between the edge gate structures GS_2. Although the three normal gate structures GS_1 are shown, the example is only for convenience of explanation and is not limited thereto.

The normal gate structure GS_1 and the edge gate structure GS_2 each overlap the first line blocking structure 110 in the third direction D3. The normal gate structure GS_1 and the edge gate structure GS_2 each overlap the second line blocking structure 210 in the third direction D3.

The plurality of gate structures GS_1 and GS_2 may include a first inner gate structure INT1_GS and a second inner gate structure INT2_GS, respectively. The first inner gate structure INT1_GS and the second inner gate structure INT2_GS may each include a gate electrode 120 and a gate insulating film 130.

The first inner gate structure INT1_GS may be disposed between the first sheet patterns NS1 adjacent to each other in the third direction D3. The first inner gate structure INT1_GS may be disposed between the first line blocking structure 110 and the first sheet pattern NS1.

The first inner gate structure INT1_GS may come into contact with the upper surface 110US of the first line blocking structure, the upper surface NS1_US of the first sheet pattern, and the lower surface NS1_BS of the first sheet pattern.

The second inner gate structure INT2_GS may be disposed between the second sheet patterns NS2 adjacent to each other in the third direction D3. The second inner gate structure INT2_GS may be disposed between the second line blocking structure 210 and the second sheet pattern NS2.

The second inner gate structure INT2_GS may come into contact with the upper surface 210US of the second line blocking structure, the upper surface NS2_US of the second sheet pattern, and the lower surface NS2_BS of the second sheet pattern.

For example, from the viewpoint of a cross-sectional view taken in the first direction D1, although the entire gate electrode 120 included in the edge gate structure GS_2 may overlap the first sheet pattern NS1 in the third direction D3, the example is not limited thereto. From the viewpoint of a cross-sectional view, although the entire gate electrode 120 included in the edge gate structure GS_2 may overlap the second sheet pattern NS2 in the third direction D3, the example is not limited thereto.

The gate electrode 120 is disposed on the first lower pattern BP1 and the second lower pattern BP2. The gate electrode 120 intersects the first lower pattern BP1 and the second lower pattern BP2.

The gate electrode 120 is disposed on the first line blocking structure 110 and the second line blocking structure 210. The gate electrode 120 overlaps the first line blocking structure 110 in the third direction D3. The gate electrode 120 overlaps the second line blocking structure 210 in the third direction D3. The gate electrode 120 may wrap the first sheet pattern NS1. The gate electrode 120 may wrap the second sheet pattern NS2.

The gate electrodes 120 may each include at least one of metal, metal alloy, conductive metal nitride, metal silicide, doped semiconductor material, conductive metal oxide and conductive metal oxynitride. The gate electrode 120 may include, for example, but not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and conductive metal oxynitride may include, but not limited to, oxidized forms of the aforementioned materials.

The gate electrode 120 may be disposed on both side surfaces of a first source/drain pattern 150, which will be described below. The gate structures GS_1 and GS_2 may be disposed on both sides of the first source/drain pattern 150 in the first direction D1. The gate electrode 120 may be disposed on both sides of a second source/drain pattern 250, which will be described below. The gate structures GS_1 and GS_2 may be disposed on both sides of the second source/drain pattern 250 in the first direction D1.

The gate insulating film 130 may extend along the upper surface of the field insulating film 105, the upper surface 110US of the first line blocking structure, and the upper surface 210US of the second line blocking structure. The gate insulating film 130 may come into contact with the upper surface 110US of the first line blocking structure and the upper surface 210US of the second line blocking structure.

The gate insulating film 130 may wrap the first sheet pattern NS1 and the second sheet pattern NS2. The gate insulating film 130 may be disposed along the periphery of the first sheet pattern NS1 and the periphery of the second sheet pattern NS2. The gate electrode 120 is disposed on the gate insulating film 130. The gate insulating film 130 is disposed between the gate electrode 120 and the first sheet pattern NS1. The gate insulating film 130 is disposed between the gate electrode 120 and the second sheet pattern NS2.

The gate insulating film 130 may include silicon oxide, silicon-germanium oxide, germanium oxide, silicon oxynitride, silicon nitride, or a high dielectric constant material having a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the gate insulating film 130 is shown as a single film, this example is only for convenience of explanation and is not limited thereto. The gate insulating film 130 may include multiple films. The gate insulating film 130 may include an interfacial film and a high dielectric constant insulating film disposed between the first sheet pattern NS1 and the gate electrode 120, and between the second sheet pattern NS2 and the gate electrode 120.

A semiconductor device according to some embodiments may include an NC (Negative Capacitance) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are electrically connected in series and the capacitance of each capacitor has a positive value, the overall capacitances decrease from the capacitance of each of the individual capacitors. On the other hand, if at least one of the capacitances of two or more capacitors electrically connected in series has a negative value, the overall capacitances may be greater than an absolute value of each of the individual capacitances, while having a positive value.

When the ferroelectric material film having the negative capacitance and the paraelectric material film having the positive capacitance are electrically connected in series, the overall capacitance values of the ferroelectric material film and the paraelectric material film electrically connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

The gate spacer 140 may be disposed on the side wall of the gate electrode 120. The gate spacer 140 may not be disposed between the first sheet patterns NS1 adjacent to each other in the third direction D3. The gate spacer 140 may not be disposed between the second sheet patterns NS2 adjacent to each other in the third direction D3.

The gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the gate spacer 140 is shown as being a single film, this example is only for convenience of explanation and is not limited thereto.

A gate capping pattern 145 may be disposed on the gate electrode 120 and the gate spacer 140. An upper surface of the gate capping pattern 145 may be disposed on the same plane as an upper surface of a first interlayer insulating film 190. The gate capping pattern 145 may be disposed between the gate spacers 140, unlike the shown example.

The gate capping pattern 145 may include, for example, at least one of silicon nitride (SiN), silicon oxynitride (SiON), silicon carbonitride (SiCN), silicon oxycarbonitride (SiOCN), and combinations thereof. The gate capping pattern 145 may include a material having an etch selectivity with respect to the interlayer insulating film 190.

A first source/drain pattern 150 may be disposed on the first lower pattern BP1. The first source/drain pattern 150 is connected to (e.g., may directly contact) the first sheet pattern NS1.

The first source/drain patterns 150 may be disposed on side surfaces of the gate structures GS_1 and GS_2. The first source/drain patterns 150 may be disposed between the gate structures GS_1 and GS_2 adjacent to each other in the first direction D1.

A second source/drain pattern 250 may be disposed on the second lower pattern BP2. The second source/drain pattern 250 is connected to the second sheet pattern NS2.

The second source/drain patterns 250 may be disposed on side surfaces of the gate structures GS_1 and GS_2. The second source/drain pattern 250 may be disposed between the gate structures GS_1 and GS_2 adjacent to each other in the first direction D1.

The first source/drain pattern 150 and the second source/drain pattern 250 may be included in the source/drain of the transistor that uses the first sheet pattern NS1 and the second sheet pattern NS2 as channel regions, respectively.

The first source/drain pattern 150 may be disposed on the first line blocking structure 110. The first line blocking structure 110 may overlap the first source/drain pattern 150 in the third direction D3.

A part of the first source/drain pattern 150 may be disposed in the first line blocking structure 110. The first source/drain pattern 150 may come into contact with the first line blocking structure 110. The first source/drain pattern 150 may be spaced apart from the first lower pattern BP1 in the third direction D3. For example, the first source/drain pattern 150 may not come into contact with the first lower pattern BP1. The first source/drain pattern 150 may be connected to the first sheet pattern NS1 on the first line blocking structure 110.

A part of the first line blocking structure 110 may be disposed between the lowermost part of the first source/drain pattern 150 and the upper surface BP1_US of the first lower pattern. In FIG. 5, a thickness t2 of the first line blocking structure 110 at the portion that overlaps the gate structures GS_1 and GS_2 in the third direction D3 is greater than a height H1 from the upper surface BP1_US of the first lower pattern to the lowermost part of the first source/drain pattern 150.

Some of the plurality of line blocking films 111 may be disposed between the lowermost part of the first source/drain pattern 150 and the upper surface BP1_US of the first lower pattern. Others or the rest of the plurality of line blocking films 111 may be separated by the first source/drain patterns 150. In other words, a part or subset of the plurality of line blocking films 111 may be positioned to be lower than the lowermost part of the first source/drain pattern 150 on the basis of or relative to the upper surface BP1_US of the first lower pattern. Another subset or the rest of the plurality of line blocking films 111 may be positioned to be higher than the lowermost part of the first source/drain pattern 150 on the basis of or relative to the upper surface BP1_US of the first lower pattern.

For example, in FIG. 5, the first sub-blocking film 111A and the second sub-blocking film 111B may extend along the upper surface BP1_US of the first lower pattern. The first sub-blocking film 111A and the second sub-blocking film 111B may be disposed between the lowermost part of the first source/drain pattern 150 and the upper surface BP1_US of the first lower pattern. The first source/drain pattern 150 may be disposed on the second sub-blocking film 111B. The first sub-blocking film 111A and the second sub-blocking film 111B overlap the first source/drain pattern 150 and the gate structures GS_1 and GS_2 in the third direction D3.

Meanwhile, each of the third sub-blocking films 111C and the fourth sub-blocking films 111D includes portions that are separated by the first source/drain pattern 150 in the first direction D1. The first source/drain pattern 150 may extend between and separate portions of the third sub-blocking films 111C and the fourth sub-blocking films 111D. The first source/drain pattern 150 may come into contact with the third sub-blocking films 111C and the fourth sub-blocking films 111D.

Since the third sub-blocking film 111C is separated by the first source/drain pattern 150, a height H2 from the upper surface BP1_US of the first lower pattern to the third sub-blocking film 111C is greater than the height H1 from the upper surface BP1_US of the first lower pattern to the lowermost part of the first source/drain pattern 150.

The second source/drain pattern 250 may be disposed on the second line blocking structure 210. The second line blocking structure 210 may overlap the second source/drain pattern 250 in the third direction D3.

A part of the second source/drain pattern 250 may be disposed inside the second line blocking structure 210. The second source/drain pattern 250 may come into contact with the second line blocking structure 210. The second source/drain pattern 250 may be spaced apart from the second lower pattern BP2 in the third direction D3. For example, the second source/drain pattern 250 may not come into contact with the second lower pattern BP2. The second source/drain pattern 250 may be connected to (e.g., may directly contact) the second sheet pattern NS2 on the second line blocking structure 210.

A part of the second line blocking structure 210 may be disposed between the lowermost part of the second source/drain pattern 250 and the upper surface BP2_US of the second lower pattern. A relationship between the first source/drain pattern 150 and the first line blocking structure 110 described with reference to FIG. 5 may also be applied between the second source/drain pattern 250 and the second line blocking structure 210.

The first source/drain pattern 150 may be disposed in a first source/drain recess 150R. The second source/drain pattern 250 may be disposed in a second source/drain recess 250R. The first source/drain recess 150R and the second source/drain recess 250R each extend in the third direction D3. The first source/drain recess 150R and the second source/drain recess 250R may be defined between gate structures GS_1 and GS_2 adjacent to each other in the first direction D1.

A bottom surface of the first source/drain recess 150R may be defined by the first line blocking structure 110. The bottom surface of the second source/drain recess 250R may be defined by the second line blocking structure 210.

In the semiconductor device according to some embodiments, side walls of the first source/drain recesses 150R may be defined by the first sheet pattern NS1 and the first inner gate structure INT1_GS. Side walls of the second source/drain recess 250R may be defined by the second sheet pattern NS2 and the second inner gate structure INT2_GS.

The first inner gate structure INT1_GS may include an upper surface which faces the lower surface NS1_BS of the first sheet pattern. The first inner gate structure INT1_GS includes a lower surface which faces the upper surface NS1_US of the first sheet pattern or the upper surface 110US of the first line blocking structure. The first inner gate structure INT1_GS includes side walls which connect the upper surface of the first inner gate structure INT1_GS and the lower surface of the first inner gate structure INT1_GS. The side walls of the first inner gate structure INT1_GS may define a part of the side walls of the first source/drain recess 150R.

Similarly to the first inner gate structure INT1_GS, the second inner gate structure INT2_GS includes side walls which connect the upper surface of the second inner gate structure INT2_GS and the lower surface of the second inner gate structure INT2_GS. The side walls of the second inner gate structure INT2_GS may define a part of the side walls of the second source/drain recess 250R.

A bottom surface of the first source/drain recess 150R may be higher than the upper surface BP1_US of the first lower pattern. Similarly, a bottom surface of the second source/drain recess 250R may be higher than the upper surface BP2_US of the second lower pattern.

The first source/drain pattern 150 comes into contact with the first sheet pattern NS1. Since the gate spacer 140 is not disposed between the adjacent first sheet patterns NS1, the first inner gate structure INT1_GS may come into contact with the first source/drain patterns 150. The gate insulating film 130 of the first inner gate structure INT1_GS may come into contact with the first source/drain pattern 150.

The second source/drain pattern 250 comes into contact with the second sheet pattern NS2. Because the gate spacer 140 is not disposed between the adjacent second sheet patterns NS2, the second inner gate structure INT2_GS may come into contact with the second source/drain pattern 250. The gate insulating film 130 of the second inner gate structure INT2_GS may come into contact with the second source/drain pattern 250.

The first source/drain pattern 150 and the second source/drain pattern 250 include a semiconductor material. The first source/drain pattern 150 and the second source/drain pattern 250 include an epitaxial semiconductor pattern.

The first source/drain pattern 150 may include, for example, at least one of silicon, silicon-germanium, and silicon carbide. The first source/drain pattern 150 may include doped n-type impurities. For example, the n-type impurity may include at least one of phosphorous (P), arsenic (As), antimony (Sb) and bismuth (Bi). Although the first source/drain pattern 150 is shown as a single film, the example is only for convenience of explanation and is not limited thereto.

The second source/drain pattern 250 may include, for example silicon-germanium. The second source/drain pattern 250 may include p-type impurities. For example, the p-type impurity may be, but not limited to, boron (B). Although the second source/drain pattern 250 is shown as a single film, this example is only for convenience of explanation, and is not limited thereto.

If the n-type impurities doped into the first source/drain pattern 150 are diffused into the first lower pattern BP1, a leakage current of the semiconductor device may increase. Accordingly, the performance and reliability of the semiconductor device may be degraded.

The first line blocking structure 110 includes a line blocking film 111, which is an oxygen-doped crystalline silicon film. The line blocking film 111 may prevent n-type impurities doped into the first source/drain pattern 150 from diffusing into the first lower pattern BP1. Alternatively, the line blocking film 111 may reduce the amount of n-type impurities diffused from the first source/drain pattern 150 to the first lower pattern BP1. Accordingly, leakage current flowing through the first lower pattern BP1 can be reduced. Alternatively, leakage current can be prevented from flowing through the first lower pattern BP1. Therefore, it is possible to enhance or improve the performance and reliability of the semiconductor device.

Similarly, the second line blocking structure 210 can prevent p-type impurities doped into the second source/drain pattern 250 from diffusing into the second lower pattern BP2. Alternatively, the second line blocking structure 210 can reduce the amount of p-type impurities diffusing from the second source/drain pattern 250 to the second lower pattern BP2. Therefore, it is possible to enhance or improve the performance and reliability of the semiconductor device.

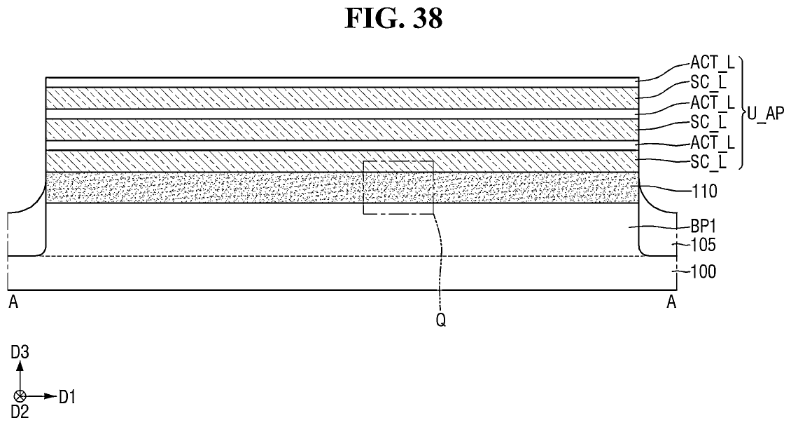

In addition, since the line blocking structures 110 and 210 include the oxygen-doped crystalline silicon film and the crystalline silicon film, the crystallinity of the first source/drain pattern 150 and the second source/drain pattern 250 can be maintained. In addition, the crystallinity of the upper pattern structure (U_AP of FIG. 38) can also be maintained in the fabricating process of forming the first sheet pattern NS1 and the second sheet pattern NS2.

Although not shown, a source/drain etching stop film may be disposed on the upper surface of the first source/drain pattern 150 and the upper surface of the second source/drain pattern 250. The source/drain etching stop film may be disposed on the upper surface of the field insulating film 105.

The first interlayer insulating film 190 may be disposed on the first source/drain pattern 150 and the second source/drain pattern 250. The first interlayer insulating film 190 may not cover the upper surface of the gate capping pattern 145.

The first interlayer insulating film 190 may include, for example, at least one of silicon oxide, silicon nitride, silicon oxynitride and a low dielectric constant material. The low dielectric constant material may include, but not limited to, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HIMD), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

A first source/drain contact 180 is disposed on the first source/drain pattern 150. The first source/drain contact 180 is connected to the first source/drain pattern 150. The first source/drain contact 180 passes through the first interlayer insulating film 190, and may be connected to the first source/drain pattern 150.

A second source/drain contact 280 is disposed on the second source/drain pattern 250. The second source/drain contact 280 is connected to the second source/drain pattern 250.

A first contact silicide film 155 may be further disposed between the first source/drain contact 180 and the first source/drain pattern 150. A second contact silicide layer 255 may be further disposed between the second source/drain contact 280 and the second source/drain pattern 250.

Although each of the first source/drain contact 180 and the second source/drain contact 280 is shown as a single film, the example is only for convenience of explanation and is not limited thereto. The first source/drain contact 180 and the second source/drain contact 280 may each include, for example, at least one of a metal, a metal alloy, conductive metal nitride, conductive metal carbide, conductive metal oxide, conductive metal carbonitride, and a two-dimensional (2D) material.

The first contact silicide film 155 and the second contact silicide layer 255 may include a metal silicide material.

The second interlayer insulating film 191 is disposed on the first interlayer insulating film 190. The second interlayer insulating film 191 may include, for example, at least one of silicon oxide, silicon nitride, silicon oxynitride, and a low dielectric constant material.

The wiring structure 205 is disposed inside the second interlayer insulating film 191. The wiring structure 205 may be connected to the first source/drain contact 180 and the second source/drain contact 280. The wiring structure 205 may include a wiring line 207 and a wiring via 206.

Although the wiring line 207 and the wiring via 206 are shown to be distinguished from each other, this example is only for convenience of explanation and is not limited thereto. That is, as an example, the wiring line 207 may be formed after the wiring via 206 is formed. As another example, the wiring via 206 and the wiring line 207 may be formed at the same time.

Although the wiring line 207 and the wiring via 206 are each shown as a single film, this example is only for convenience of explanation and is not limited thereto. The wiring line 207 and the wiring via 206 may each include, for example, at least one of a metal, a metal alloy, conductive metal nitride, conductive metal carbide, conductive metal oxide, conductive metal carbonitride, and a two-dimensional (2D) material.

For example, the upper surface of the first source/drain contact 180 of the portion connected to the wiring structure 205 may be disposed on the same plane as the upper surface of the first source/drain contact 180 of the portion not connected to the wiring structure 205.

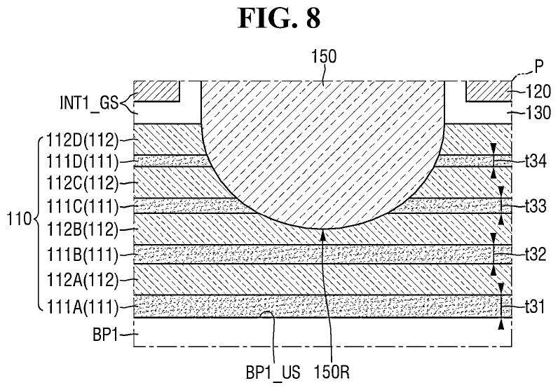

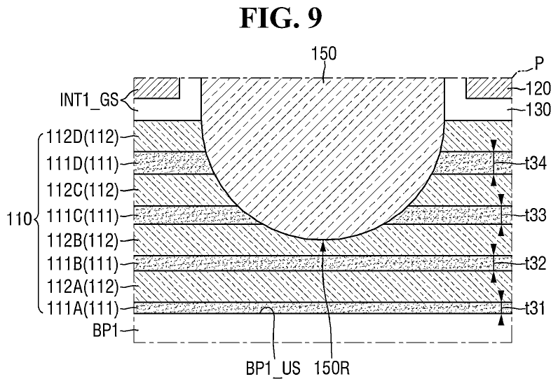

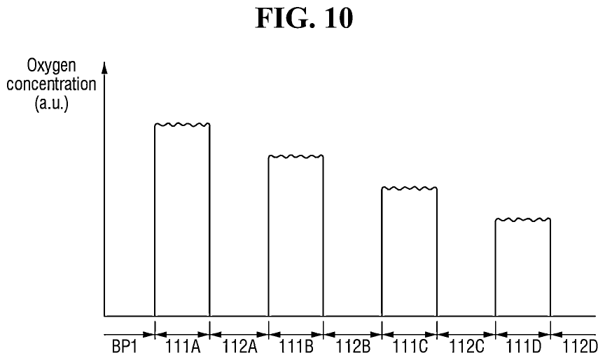

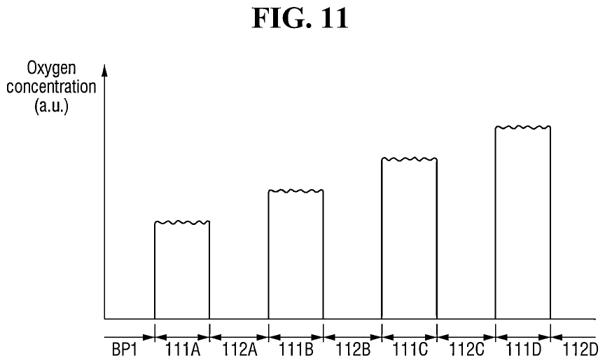

FIGS. 8 and 9 are diagrams for explaining a semiconductor device according to some embodiments, respectively. FIGS. 10 and 11 are diagrams for explaining a semiconductor device according to some embodiments, respectively. For convenience of explanation, the explanation will focus on points that are different from those explained using FIGS. 1 to 7.

For reference, FIGS. 8 and 9 are enlarged views of a portion P of FIG. 2. FIGS. 10 and 11 are diagrams schematically showing the concentration of oxygen along the SCAN LINE of FIG. 5. The following description will focus on the first line blocking structure 110. However, it is apparent that the description of the first line-blocking structure 110 may also apply to the second line-blocking structure 210.

Referring to FIGS. 8 and 9, in the semiconductor device according to some embodiments, the line blocking films 111 included in the first line blocking structure 110 may have different thicknesses from each other.

A thickness t31 of the first sub-blocking film 111A, a thickness t32 of the second sub-blocking film 111B, a thickness t33 of the third sub-blocking film 111C, and a thickness t34 of the fourth sub-blocking film 111D may be different from each other.

In FIG. 8, the thickness of the line blocking film 111 included in the first line blocking structure 110 may decrease, as it moves away from (i.e., with distance from) the first lower pattern BP1. The thickness t31 of the first sub-blocking film 111A may be greater than the thickness t32 of the second sub-blocking film 111B. The thickness t32 of the second sub-blocking film 111B may be greater than the thickness t33 of the third sub-blocking film 111C. The thickness t33 of the third sub-blocking film 111C may be greater than the thickness t34 of the fourth sub-blocking film 111D.

As the thickness of the line blocking film 111 decreases, a strain effect of the first line blocking structure 110 on the upper pattern structure (U_AP of FIG. 38) may decrease. Since the strain effect decreases, the crystallinity of the upper pattern structure (U_AP of FIG. 38) may be improved.

In FIG. 9, the thickness of the line blocking film 111 included in the first line blocking structure 110 may increase with distance from the first lower pattern BP1. The thickness t31 of the first sub-blocking film 111A may be thinner than the thickness t32 of the second sub-blocking film 111B. The thickness t32 of the second sub-blocking film 111B may be thinner than the thickness t33 of the third sub-blocking film 111C. The thickness t33 of the third sub-blocking film 111C may be thinner than the thickness t34 of the fourth sub-blocking film 111D.

As the thickness of the line blocking film 111 increases, the diffusion of n-type impurities can be blocked more effectively. Since the amount of n-type impurities diffused into the first lower pattern BP1 further decreases, leakage current flowing through the first lower pattern BP1 can be further reduced.

Unlike the example shown in FIGS. 8 and 9, as an example, the thickness of the line blocking film 111 included in the first line blocking structure 110 may decrease and then increase with distance from the first lower pattern BP1. As another example, the thickness of the line blocking film 111 included in the first line blocking structure 110 may increase and then decrease with distance from the first lower pattern BP1. As still another example, the thickness of the line blocking film 111 included in the first line blocking structure 110 may decrease and then be kept constant with distance from the first lower pattern BP1. As yet another example, the thickness of the line blocking film 111 included in the first line blocking structure 110 may increase and then be kept constant with distance from the first lower pattern BP1.

Referring to FIGS. 10 and 11, in the semiconductor devices according to some embodiments, the concentration of oxygen doped into the line blocking film 111 in the first line blocking structure 110 may differ from each other.

The concentration of oxygen doped into the first sub-blocking film 111A, the concentration of oxygen doped into the second sub-blocking film 111B, the concentration of oxygen doped into the third sub-blocking film 111C, and the concentration of oxygen doped into the fourth sub-blocking film 111D may differ from each other.

In FIG. 10, the concentration of oxygen doped into the sub-blocking films 111A, 111B, 111C and 111D may decrease with distance from the first lower pattern BP1. The concentration of oxygen doped into the first sub-blocking film 111A may be higher than the concentration of oxygen doped into the second sub-blocking film 111B. The concentration of oxygen doped into the second sub-blocking film 111B may be higher than the concentration of oxygen doped into the third sub-blocking film 111C. The concentration of oxygen doped into the third sub-blocking film 111C may be higher than the concentration of oxygen doped into the fourth sub-blocking film 111D.

As the concentration of oxygen doped into the line blocking film 111 decreases, a lattice distortion of the crystalline silicon film may decrease. Since the lattice distortion of the crystalline silicon film decreases, the crystallinity of the upper pattern structure (U_AP of FIG. 38) may be improved.

In FIG. 11, the concentration of oxygen doped into the sub-blocking films 111A, 111B, 111C and 111D may increase with distance from the first lower pattern BP1. The concentration of oxygen doped into the first sub-blocking film 111A may be lower than the concentration of oxygen doped into the second sub-blocking film 111B. The concentration of oxygen doped into the second sub-blocking film 111B may be lower than the concentration of oxygen doped into the third sub-blocking film 111C. The concentration of oxygen doped into the third sub-blocking film 111C may be lower than the concentration of oxygen doped into the fourth sub-blocking film 111D.

As the concentration of oxygen doped into the line blocking film 111 increases, the diffusion of n-type impurities can be blocked more effectively. Accordingly, the leakage current flowing through the first lower pattern BP1 can be further reduced.

Unlike the example shown in FIGS. 10 and 11, as an example, the concentration of oxygen doped into the line blocking film 111 may decrease and then increase with distance from the first lower pattern BP1. As another example, the concentration of oxygen doped into the line blocking film 111 may increase and then decrease with distance from the first lower pattern BP1. As still another example, the concentration of oxygen doped into the line blocking film 111 may decrease and then be kept constant with distance from the first lower pattern BP1. As yet another example, the concentration of oxygen doped into the line blocking film 111 may increase and then be kept constant with distance from the first lower pattern BP1.

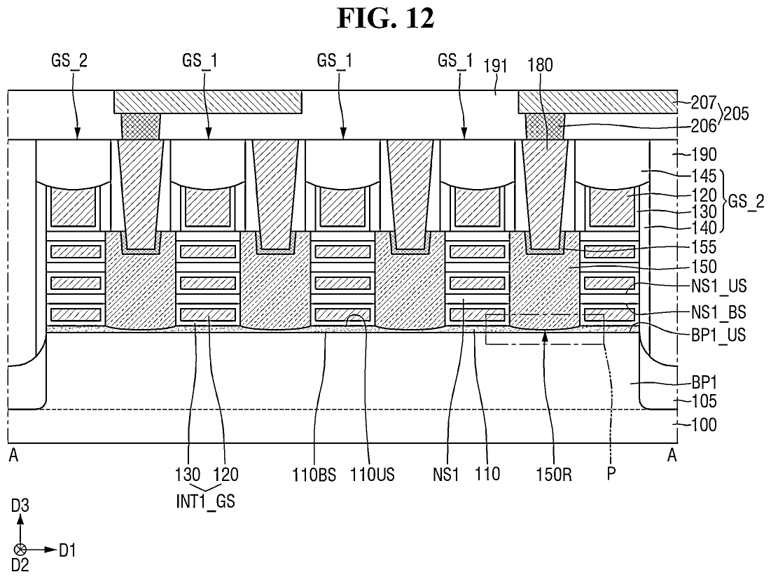

FIGS. 12 to 14 are diagrams for explaining a semiconductor device according to some embodiments. For convenience of explanation, the explanation will focus on points that are different from those explained using FIGS. 1 to 7.

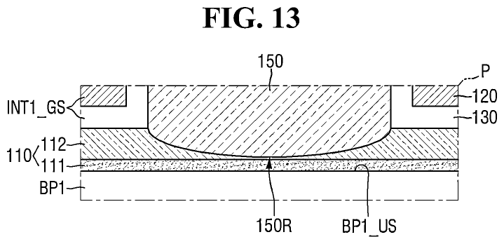

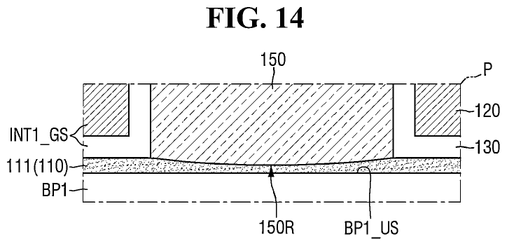

For reference, FIG. 12 is a diagram for explaining a semiconductor device according to some embodiments. FIGS. 13 and 14 are enlarged views of the portion P of FIG. 12. Since a second line blocking structure 210 may have the same structure as the first line blocking structure 110, the first line blocking structure 110 will be mainly described.

Referring to FIGS. 12 to 14, in the semiconductor devices according to some embodiments, the first line blocking structure 110 may include a single line blocking film 111.

The line blocking film 111 may be disposed between the first source/drain pattern 150 and the first lower pattern BP1. The first source/drain pattern 150 may not penetrate the line blocking film 111. The line blocking film 111 may not be separated by the first source/drain pattern 150.

In FIG. 13, the first line blocking structure 110 may include a single line insertion semiconductor film 112. The line insertion semiconductor film 112 may be disposed on the line blocking film 111. The line blocking film 111 may be disposed between the line insertion semiconductor film 112 and the first lower pattern BP1.

In FIG. 14, no line insertion semiconductor film may be disposed on the line blocking film 111. The line blocking film 111 may come into contact with the first inner gate structure INT1_GS.

Unlike the example shown in FIGS. 13 and 14, an additional line insertion semiconductor film may be disposed between the line blocking film 111 and the first lower pattern BP1.

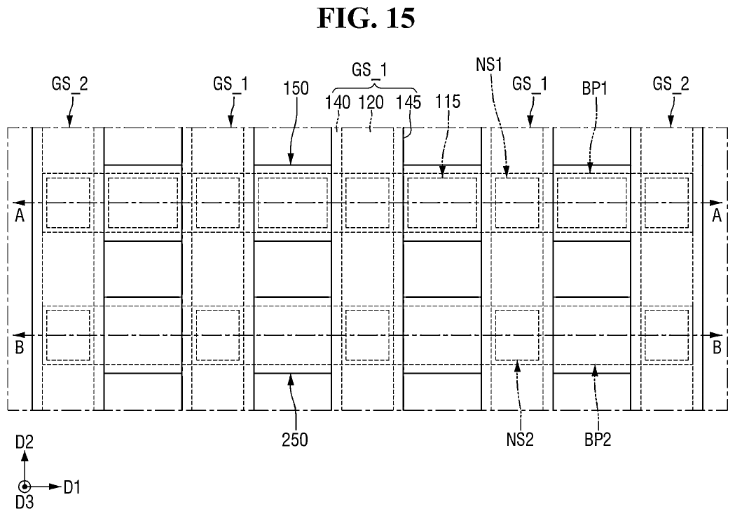

FIGS. 15 to 20 are diagrams for explaining a semiconductor device according to some embodiments. For convenience of explanation, the explanation will focus on points that are different from those explained using FIGS. 1 to 7.

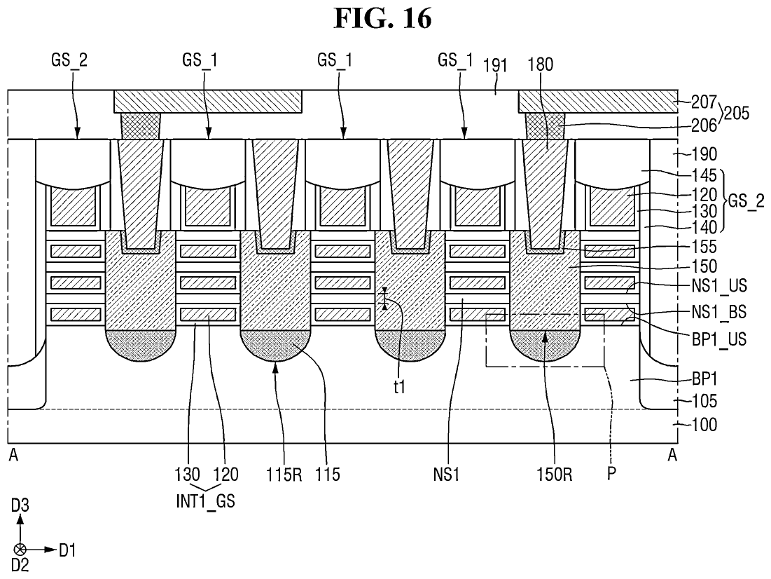

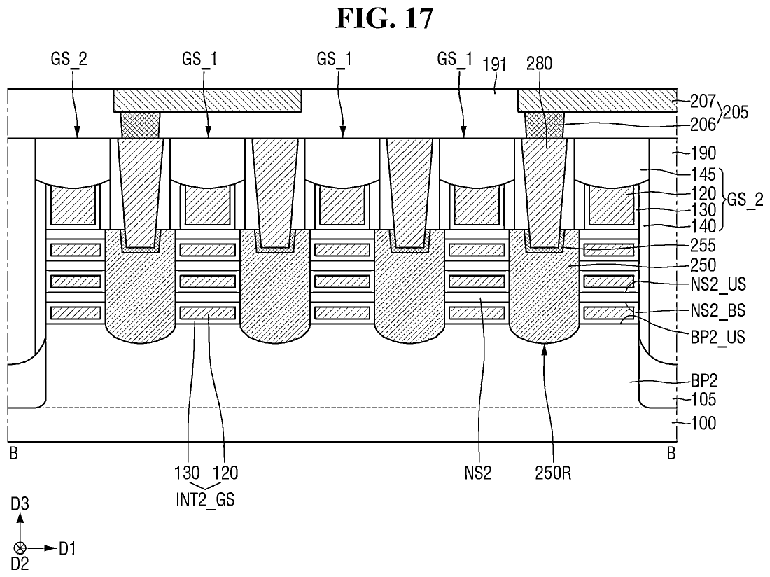

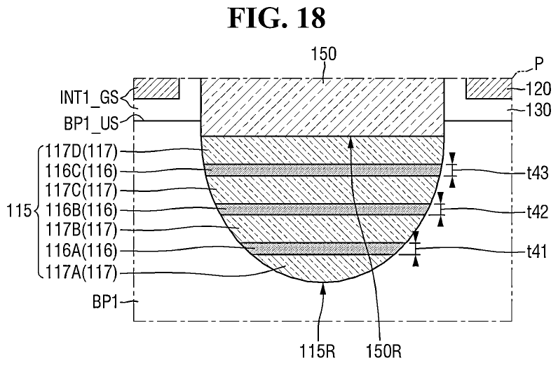

For reference, FIG. 15 is a schematic plan view for explaining a semiconductor device according to some embodiments. FIGS. 16 and 17 are cross-sectional views taken along A-A and B-B of FIG. 15. FIG. 18 to 20 are enlarged views of the portion P of FIG. 16.

Referring to FIGS. 15 to 19, a semiconductor device according to some embodiments may include a point blocking structure 115.

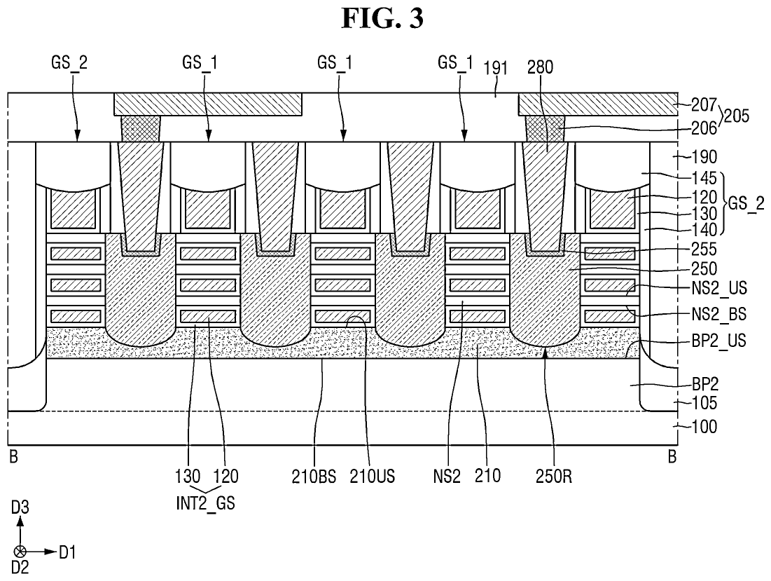

The first line blocking structure (110 of FIG. 2) is not disposed on the first lower pattern BP1. The second line blocking structure (210 of FIG. 3) is not disposed on the second lower pattern BP2.

The point blocking structure 115 may be disposed between the first lower pattern BP1 and the first source/drain pattern 150. As an example, the point blocking structure is not disposed between the second lower pattern BP2 and the second source/drain pattern 250. An additional point blocking structure may be disposed between the second lower pattern BP2 and the second source/drain pattern 250 in some embodiments, unlike the shown example. If an additional point blocking structure is disposed between the second lower pattern BP2 and the second source/drain pattern 250, the description of the point blocking structure 115 to be described below may apply to the description of the additional point blocking structure.

The point blocking structure 115 may be disposed on the first lower pattern BP1. The first lower pattern BP1 may include a blocking structure recess 115R. The point blocking structure 115 is disposed in the blocking structure recess 115R, for example, between the source drain pattern 150 and the bottom of the blocking structure recess 115R. The point blocking structure 115 comes into contact with the first lower pattern BP1.

The point blocking structure 115 overlaps the first source/drain pattern 150 in the third direction D3. The point blocking structure 115 comes into contact with the first source/drain pattern 150. The point blocking structure 115 may not overlap the gate electrode 120 of the gate structures GS_1 and GS_2 in the third direction D3.

An upper surface BP1_US of the first lower pattern may come into contact with the gate insulating film 130 of the first inner gate structure INT1_GS. An upper surface BP2_US of the second lower pattern may come into contact with the gate insulating film 130 of the second inner gate structure INT2_GS.

The point blocking structure 115 may include at least one or more point blocking films 116. The point blocking structure 115 may include a point insertion semiconductor film 117. At least one or more point blocking films 116 may not overlap the gate electrodes 120 of the gate structures GS_1 and GS_2 in the third direction D3.

As an example, the number of point insertion semiconductor films 117 may be the same as the number of point blocking films 116. As another example, the number of point insertion semiconductor films 117 may be less than the number of point blocking films 116 by one. As yet another example, the number of point insertion semiconductor films 117 may be greater than the number of point blocking films 116 by one.

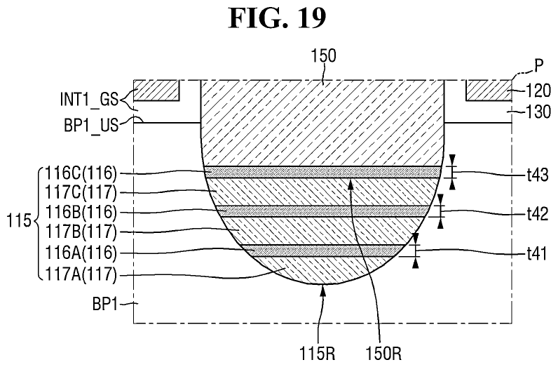

In FIGS. 18 and 19, although the point blocking structure 115 is shown to include a plurality of point blocking films 116 and a plurality of point insertion semiconductor films 117, the example is not limited thereto. The point blocking structure 115 may include one point blocking film 116.

The point blocking film 116 and the point insertion semiconductor film 117 may be alternately stacked in a blocking structure recess 115R. The point blocking structure 115 may have a superlattice structure in which the point blocking films 116 and the point insertion semiconductor films 117 are alternately stacked.

The point blocking film 116 may be an oxygen-doped crystalline silicon film. The point blocking film 116 is in a state in which the crystalline silicon film is doped with oxygen. The point insertion semiconductor film 117 may be a crystalline silicon film. Since the point blocking film 116 and the point insertion semiconductor film 117 are formed using an epitaxial growth method, the point blocking film 116 and the point insertion semiconductor film 117 may be epitaxial patterns.

In FIGS. 18 and 19, the point blocking film 116 may include multiple sub-blocking films 116A, 116B and 116C. Although the point blocking film 116 is shown to include three sub-blocking films 116A, 116B and 116C, the example is only for convenience of explanation and not limited thereto. The point blocking film 116 may include two sub-blocking films, or may include four or more sub-blocking films.

The fifth to seventh sub-blocking films 116A, 116B and 116C may be sequentially disposed on the first lower pattern BP1. The fifth to seventh sub-blocking films 116A, 116B and 116C are spaced apart from each other in the third direction D3. The fifth sub-blocking film 116A may be disposed at the lowermost part among the sub-blocking films 116A, 116B and 116C. The seventh sub-blocking film 116C may be disposed on the uppermost part among the sub-blocking films 116A, 116B and 116C.

Although a thickness t41 of the fifth sub-blocking film 116A, a thickness t42 of the sixth sub-blocking film 116B, and a thickness t43 of the seventh sub-blocking film 116C may be the same, the example is not limited thereto. The thickness t41 of the fifth sub-blocking film 116A, the thickness t42 of the sixth sub-blocking film 116B, and the thickness t43 of the seventh sub-blocking film 116C are each smaller than the thickness of the first sheet pattern NS1.

As an example, the thickness of the point blocking film 116 included in the point blocking structure 115 may decrease with distance from the substrate 100, as described in FIG. 8. As another example, the thickness of the point blocking film 116 included in the point blocking structure 115 may increase with distance from the substrate 100, as described in FIG. 9. As yet another example, the thickness of the point blocking film 116 included in the point blocking structure 115 may decrease and then increase with distance from the substrate 100. As another example, the thickness of the point blocking film 116 included in the point blocking structure 115 may increase and then decrease with distance from the substrate 100. As yet another example, the thickness of the point blocking film 116 included in the point blocking structure 115 may decrease and then be kept constant with distance from the substrate 100. As yet another example, the thickness of the point blocking film 116 included in the point blocking structure 115 may increase and then be kept constant with distance from the substrate 100.

The concentrations of oxygen contained in the fifth to seventh sub-blocking films 116A, 116B and 116C may be the same, but are not limited thereto.

As an example, the concentration of oxygen doped into the point blocking films 116A, 116B and 116C may decrease with distance from the substrate 100, as described in FIG. 10. As another example, the concentration of oxygen doped into point blocking films 116A, 116B and 116C may increase with distance from substrate 100, as described in FIG. 11. As yet another example, the concentration of oxygen doped into the point blocking films 116A, 116B and 116C may decrease and then increase with distance from substrate 100. As yet another example, the concentration of oxygen doped into the point blocking films 116A, 116B and 116C may increase and then decrease with distance from the substrate 100. As another example, the concentration of oxygen doped into the point blocking films 116A, 116B and 116C may decrease and then be kept constant with distance from the substrate 100. As another example, the concentration of oxygen doped into the point blocking films 116A, 116B and 116C may increase and then be kept constant with distance from the substrate 100.

In FIG. 18, the point insertion semiconductor film 117 may include fifth to eighth sub-insertion semiconductor films 117A, 117B, 117C and 117D. The sub-blocking films 116A, 116B and 116C may be disposed between the sub-insertion semiconductor films 117A, 117B, 117C and 117D adjacent to each other in the third direction D3. The stacked structure of the point blocking structure 115 may terminate with the point insertion semiconductor film 117D. The first source/drain pattern 150 may come into contact with the point insertion semiconductor film 117D.

In FIG. 19, the point insertion semiconductor film 117 may include fifth to seventh sub-insertion semiconductor films 117A, 117B and 117C. The stacked structure of point blocking structure 115 may terminate with the point blocking film 116C. The first source/drain pattern 150 may come into contact with the point blocking film 116C.

Unlike the example shown in FIGS. 18 and 19, the fifth sub-insertion semiconductor film 117A may not be disposed below the fifth sub-blocking film 116A. The stacked structure of the point blocking structure 115 may start with the fifth sub-blocking film 116A (e.g. at the bottom of the recess 115R).

The thickness of the pair of point blocking films 116 and point insertion semiconductor films 117 may be, for example, 10 Å to 100 Å.

In FIGS. 18 and 19, each of the fifth to seventh sub-blocking films 116A, 116B and 116C may have a flat plate shape (e.g., with opposing surfaces that are substantially planar) in a cross-sectional view.

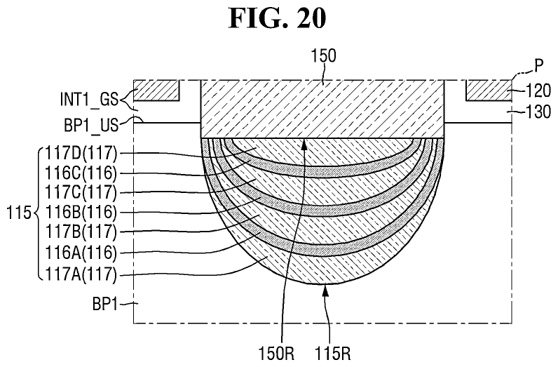

In FIG. 20, each of the fifth to seventh sub-blocking films 116A, 116B and 116C may have a curved shape in a cross-sectional view. For example, each of the fifth to seventh sub-blocking films 116A, 116B and 116C may have a curved shape that is convex downward or protruding toward the bottom of the recess 115R. Each of the fifth to seventh sub-blocking films 116A, 116B and 116C may have a shape that is convex toward the substrate 100.

The first source/drain pattern 150 may be disposed on the point blocking structure 115. The first source/drain pattern 150 may be connected to the first sheet pattern NS1 on the point blocking structure 115.

When the point blocking structure 115 fills the entire blocking structure recess 115R, the first source/drain pattern 150 may not come into contact with the first lower pattern BP1. When the point blocking structure 115 partially fills the blocking structure recess 115R, the first source/drain pattern 150 may come into contact with the first lower pattern BP1.

The first source/drain recess 150R may be defined on the point blocking structure 115. At least a part of the bottom surface of the first source/drain recess 150R may be defined by the point blocking structure 115.

A bottom surface of the second source/drain recess 250R may be defined by the second lower pattern BP2. The second source/drain pattern 250 may come into contact with the second lower pattern BP2.

Unlike the shown example, when an additional point blocking structure is disposed between the second lower pattern BP2 and the second source/drain pattern 250, at least a part of the bottom surface of the second source/drain recess 250R may be defined by an additional blocking structure.

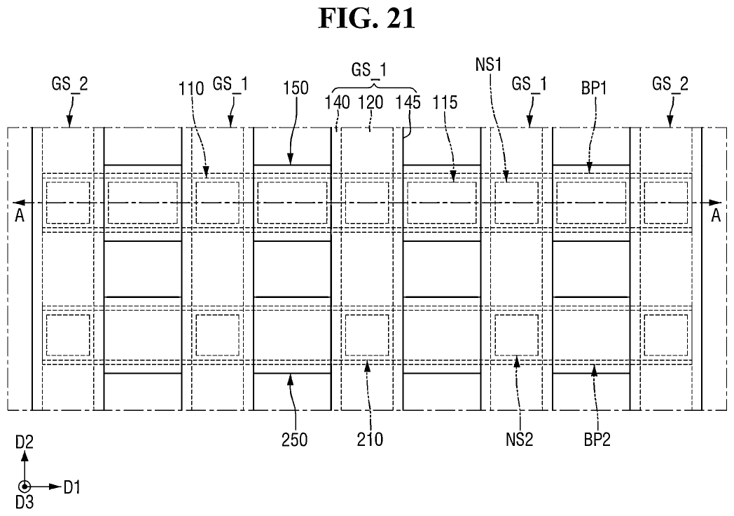

FIGS. 21 to 25 are diagrams for explaining a semiconductor device according to some embodiments. For convenience of explanation, the explanation will focus on points that are different from those explained using FIGS. 1 to 7.

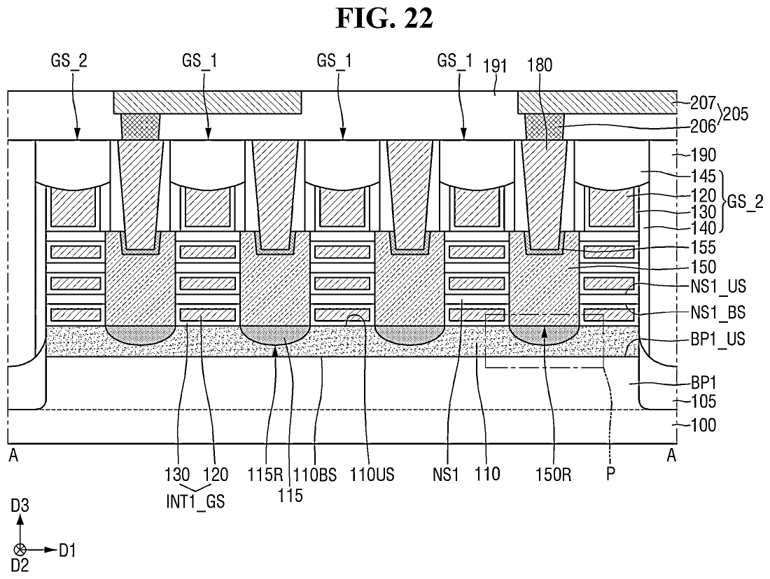

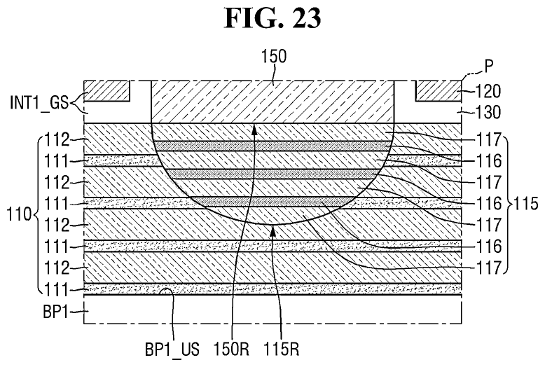

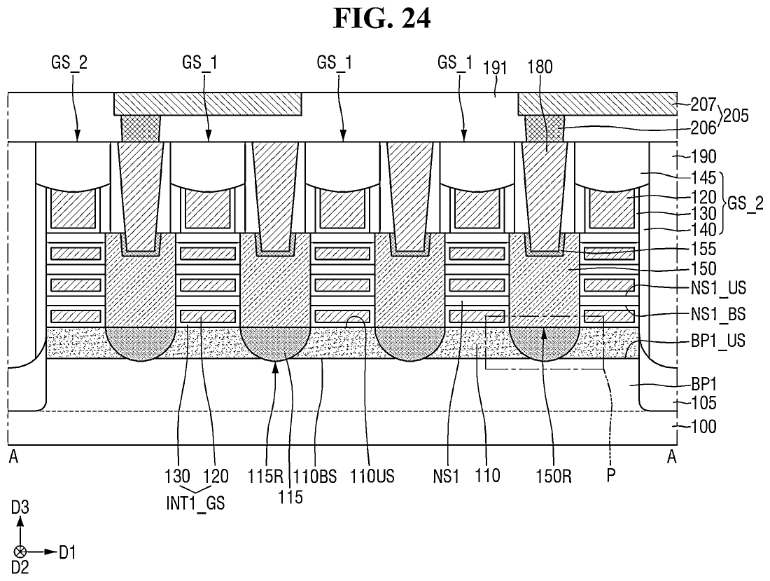

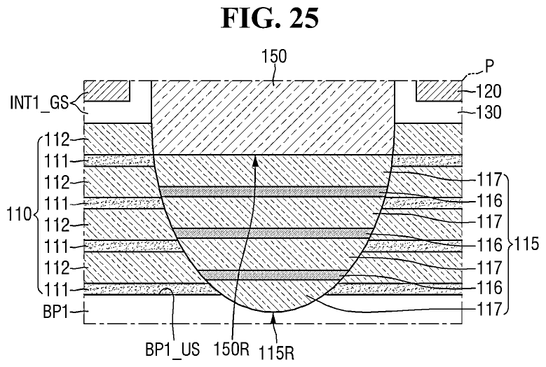

For reference, FIG. 21 is a schematic plan view for explaining a semiconductor device according to some embodiments. FIGS. 22 and 24 are cross-sectional views taken along line A-A of FIG. 21, respectively. FIG. 23 is an enlarged view of a portion P of FIG. 22, and FIG. 25 is an enlarged view of the portion P of FIG. 24.

Although not shown, a cross-sectional view taken in the first direction D1 along the second lower pattern BP2 may be the same as that of FIG. 3.

Referring to FIGS. 21 to 25, a semiconductor device according to some embodiments may include a point blocking structure 115.

The point blocking structure 115 may be disposed below the first source/drain pattern 150. The point blocking structure 115 and the first line blocking structure 110 may be disposed on the first lower pattern BP1.

The first line blocking structure 110 and the point blocking structure 115 may be blocking structures disposed on the first lower pattern BP1.

A second line blocking structure 210 may be disposed on the second lower pattern BP2. However, the point blocking structure may not be disposed below the second source/drain pattern 250. Unlike the example explained above, an additional point blocking structure may be disposed below the second source/drain pattern 250. If the additional point blocking structure is disposed on the second lower pattern BP2, the shape in which the additional point blocking structure is disposed may be the same as one of the shape in which the point blocking structure 115 is disposed in FIG. 24 or the shape in which the point blocking structure 115 is disposed in FIG. 22.

Since a structural description of the point blocking structure 115 may be substantially the same as that described using FIGS. 16 to 20, the description thereof will not be provided.

In FIGS. 22 and 23, the first line blocking structure 110 may include a blocking structure recess 115R. The blocking structure recess 115R may be formed in the first line blocking structure 110. The blocking structure recess 115R may be defined by the first line blocking structure 110.

The point blocking structure 115 may be disposed on the first line blocking structure 110. The point blocking structure 115 may not come into contact with the first lower pattern BP1. The point blocking structure 115 does not penetrate the first line blocking structure 110.

In FIGS. 24 and 25, the blocking structure recess 115R may be formed inside the first line blocking structure 110 and the first lower pattern BP1. The blocking structure recess 115R may be defined by the first line blocking structure 110 and the first lower pattern BP1.

The point blocking structure 115 may come into contact with the first lower pattern BP1. The point blocking structure 115 may penetrate the first line blocking structure 110.

In FIGS. 23 and 25, height levels of each of the fifth to seventh sub-blocking films 116A, 116B and 116C are shown as being different from height levels of each of the first to fourth sub-blocking films 111A, 111B, 111C and 111D (i.e., such that the sub-blocking films 116A-C are non-coplanar with the sub-blocking films 111A-D), the example is not limited thereto.

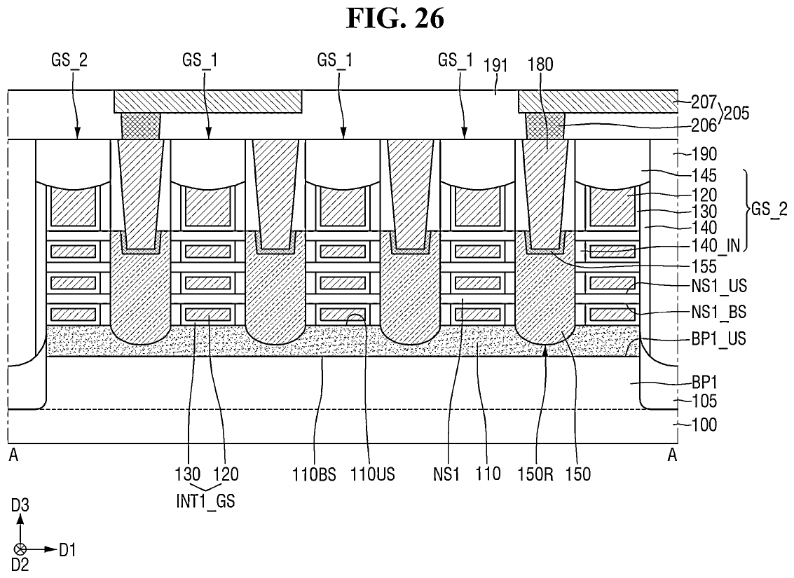

FIGS. 26 to 30 are diagrams for explaining a semiconductor device according to some embodiments, respectively. For convenience of explanation, the explanation will focus on points that are different from those explained using FIGS. 1 to 7.

Referring to FIG. 26, in the semiconductor device according to some embodiments, the gate structures GS_1 and GS_2 may further include a plurality of inner spacers 140_IN disposed between first sheet patterns NS1 adjacent to each other in the third direction D3.

The plurality of inner spacers 140_IN may be disposed between the first sheet patterns NS1 adjacent to each other in the third direction D3, and between the first line blocking structure 110 and the first sheet patterns NS1. The inner spacer 140_IN may be disposed between the upper surface 110US of the first line blocking structure and the lower surface NS1_BS of the first sheet pattern, and between the upper surface NS1_US of the first sheet pattern and the lower surface NS1_BS of the first sheet pattern facing in the third direction D3.

The inner spacer 140_IN is disposed between the first inner gate structure INT1_GS and the first source/drain pattern 150. Since the inner spacer 140_IN is disposed, the first inner gate structure INT1_GS does not come into contact with the first source/drain pattern 150. The side walls of the first source/drain recess 150R may be defined by the first sheet pattern NS1 and the inner spacer 140_IN.

The inner spacer 140_IN may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

For example, no inner spacer may be disposed between the second inner gate structure (INT2_GS of FIG. 3) and the second source/drain pattern 250.

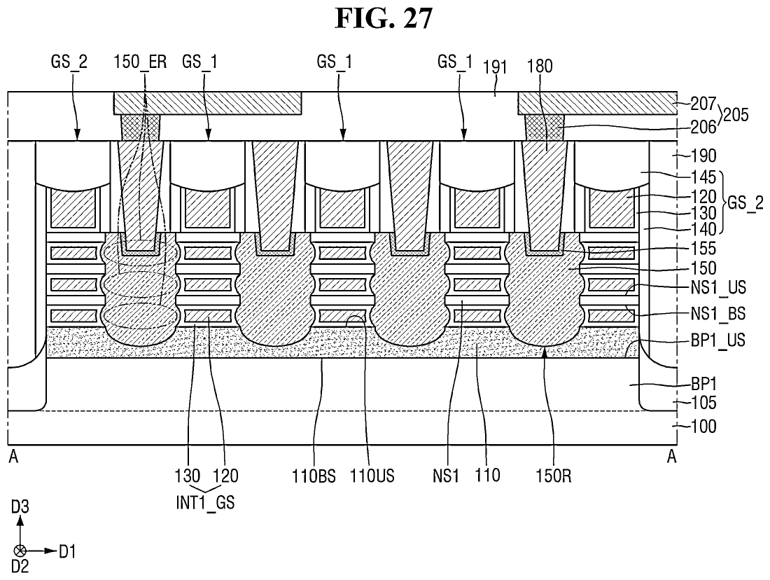

Referring to FIG. 27, in the semiconductor devices according to some embodiments, a first source/drain recess 150R may include a plurality of first width extension regions 150_ER.

Each of the first width extension regions 150_ER may be defined above the upper surface 110US of the first line blocking structure.

The first width extension region 150_ER may be defined between the first sheet patterns NS1 adjacent to each other in the third direction D3. The first width extension region 150_ER may be defined between the first line blocking structure 110 and the first sheet pattern NS1. The first width extension region 150_ER may extend between the first sheet patterns NS1 adjacent to each other in the third direction D3. The first width extension region 150_ER may be defined between the first inner gate structures INT1_GS adjacent to each other in the first direction D1.

As it moves away or with distance from the upper surface 110US of the first line blocking structure, the width expansion region 150_ER of each first recess may include a portion having a width increased in the first direction D1, and a portion having a width decreased in the first direction D1. For example, the width of the first width extension region 150_ER may increase and then decrease with distance from the upper surface 110US of the first line blocking structure.

In each first width expansion region 150_ER, the point on which the width of the first width expansion region 150_ER is the maximum is located between the first line blocking structure 110 and the first sheet pattern NS1 or between the first sheet patterns NS1_N adjacent to each other in the third direction D3. As such, sidewalls of the first source/drain recess 150R may laterally protrude between the first line blocking structure 110 and the first sheet pattern NS1 or between the first sheet patterns NS1_N adjacent to each other in the third direction D3.

Although not shown, as an example, the second source/drain recesses (250R of FIG. 3) may include a plurality of second width extension regions. A description of the second width extension region may be similar to the description of the first width extension region 150_ER described above.

Unlike the shown example, one of the first source/drain recess 150R and the second source/drain recess (250R of FIG. 3) may include the width extension regions, and the other may not include the width extension region.

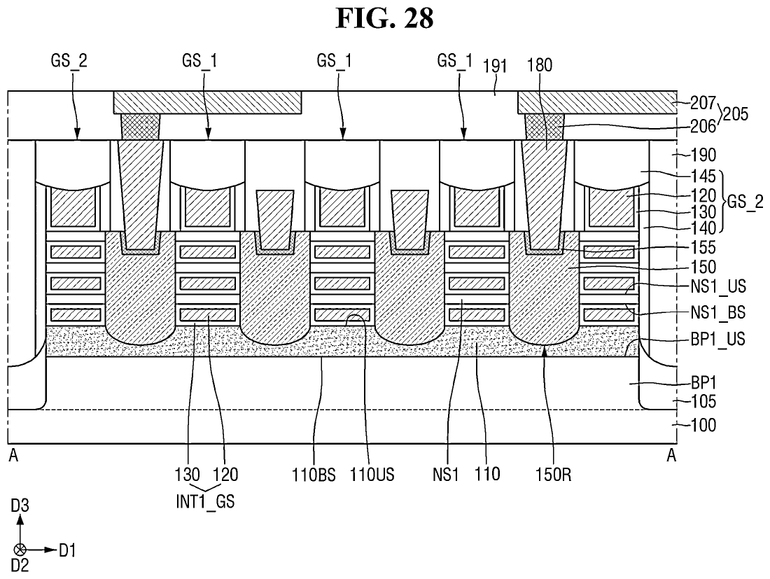

Referring to FIG. 28, in the semiconductor device according to some embodiments, the upper surface of the first source/drain contact 180 of a portion not connected to the wiring structure 205 is lower than the upper surface of the gate capping pattern 145.

The upper surface of the first source/drain contact 180 of the portion connected to the wiring structure 205 is lower than the upper surface of the first source/drain contact 180 of the portion not connected to the wiring structure 205.

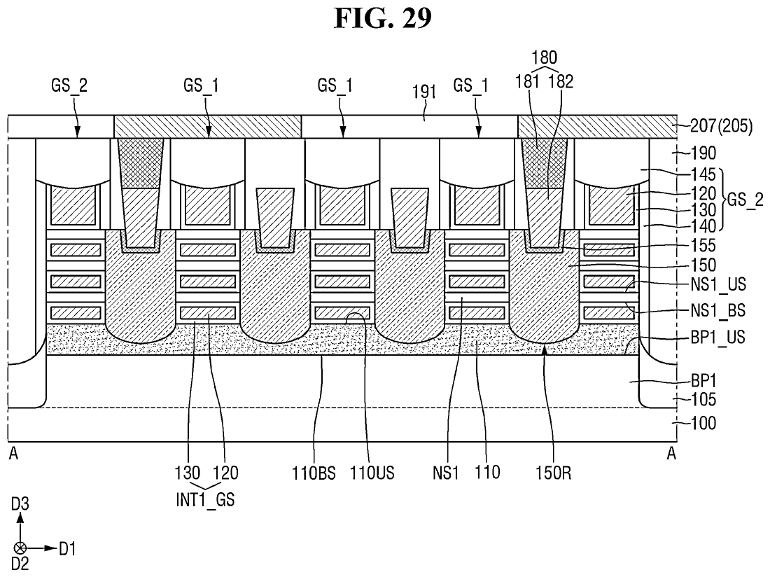

Referring to FIG. 29, in the semiconductor device according to some embodiments, the first source/drain contact 180 includes a lower source/drain contact 182 and an upper source/drain contact 181.

The upper source/drain contact 181 may be disposed in the portion connected to the wiring structure 205. On the other hand, the upper source/drain contact 181 may not be disposed in the portion not connected to the wiring structure 205.

The wiring line 207 may be connected to the first source/drain contact 180 without a wiring via (206 of FIG. 2). The wiring structure 205 may not include the wiring via (206 of FIG. 2).

Although each of the lower source/drain contact 182 and the upper source/drain contact 181 is shown as a single film, the example is only for convenience of explanation and is not limited thereto. The lower source/drain contact 182 and the upper source/drain contact 181 may each include, for example, at least one of a metal, a metal alloy, a conductive metal nitride, a conductive metal carbide, a conductive metal oxide, a conductive metal carbonitride, and a two-dimensional material (2D).

Although not shown, the second source/drain contact 280 may have the same shape as described using FIGS. 27 and 28.

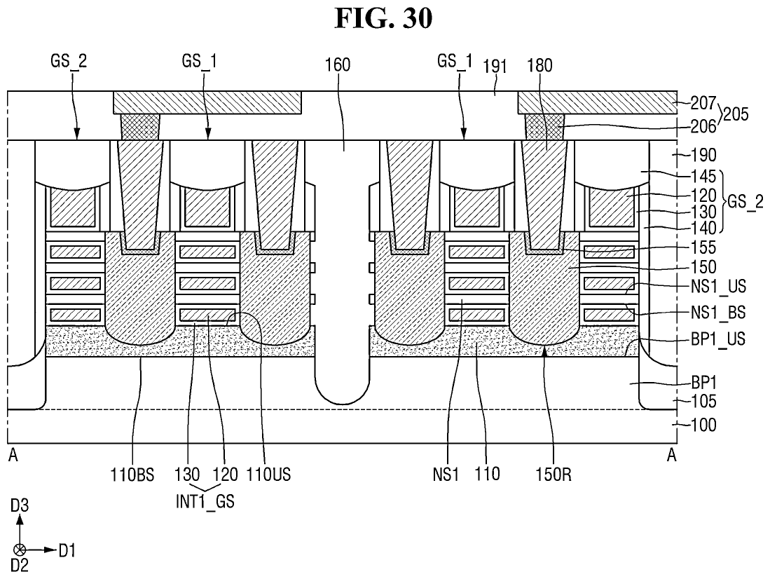

Referring to FIG. 30, the semiconductor device according to some embodiments may further include an element isolation structure 160 that isolates the first lower pattern BP1.

The first line blocking structure 110 may be isolated by the element isolation structure 160. The lowermost part of the element isolation structure 160 is lower than the lower surface 110BS of the first line blocking structure.

The element isolation structure 160 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the element isolation structure 160 is shown as a single film, the example is only for convenience of explanation and is not limited thereto.

Although not shown, the element isolation structure 160 may isolate the second line blocking structure (210 of FIG. 3).

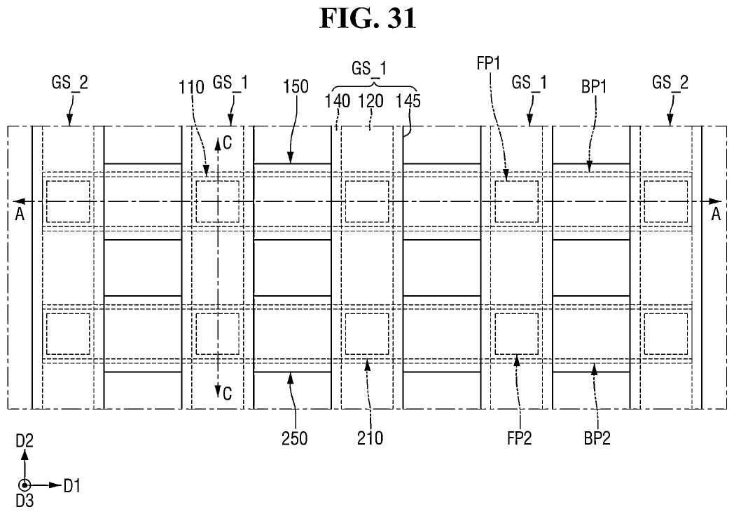

FIGS. 31 to 34 are diagrams for explaining a semiconductor device according to some embodiments. For convenience of explanation, the explanation will focus on the points different from those explained using FIGS. 1 to 7.

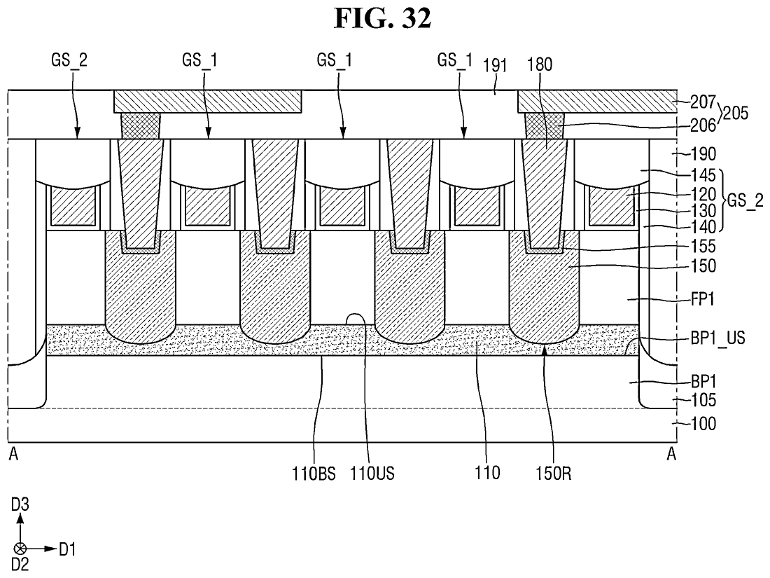

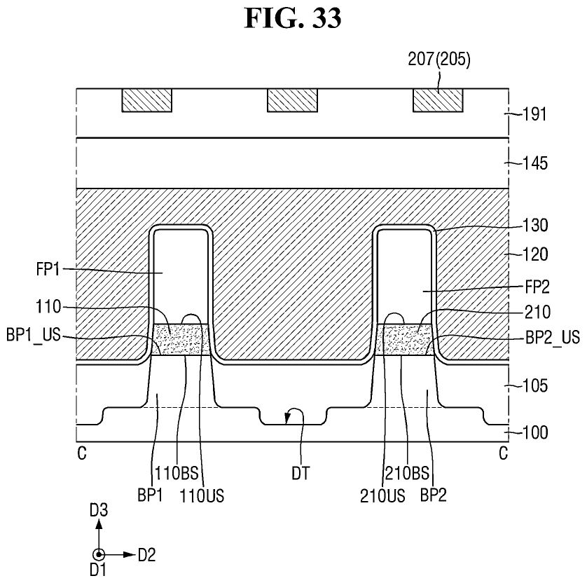

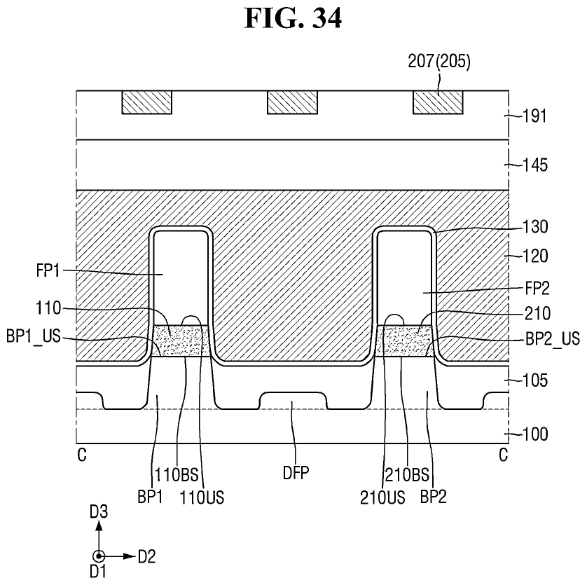

For reference, FIG. 31 is a schematic plan view for explaining a semiconductor device according to some embodiments. FIG. 32 is a cross-sectional view taken along line A-A of FIG. 31. FIGS. 33 and 34 are exemplary cross-sectional views taken along C-C of FIG. 31, respectively. Although not shown, a cross-sectional view taken along the second lower pattern BP2 in the first direction D1 may be similar to FIG. 32.

Referring to FIGS. 31 to 34, a semiconductor device according to some embodiments may include a first fin channel pattern FP1 and a second fin channel pattern FP2.

The first fin channel pattern FP1 may be disposed on the upper surface 110US of the first line blocking structure. The first fin channel pattern FP1 may come into contact with the first line blocking structure 110.

The second fin channel pattern FP2 may be disposed on the upper surface of the second line blocking structure 210. The second fin channel pattern FP2 may come into contact with the second line blocking structure 210.

The first fin channel pattern FP1 and the second fin channel pattern FP2 may each include one of silicon or germanium which is an elemental semiconductor material, a group IV-IV compound semiconductor or a group 111-V compound semiconductor. Each first fin channel pattern FP1 may include the same material as the first lower pattern BP1, or may include a different material from the first lower pattern BP1. Each second fin channel pattern FP2 may include the same material as the second lower pattern BP2, or may include a different material from the second lower pattern BP2. The first fin channel pattern FP1 and the second fin channel pattern FP2 may include the same material or may include different materials. In the semiconductor device according to some embodiments, the first fin channel pattern FP1 and the second fin channel pattern FP2 may each be a silicon fin channel pattern including silicon.

In FIG. 33, the first lower pattern BP1 and the second lower pattern BP2 may each be disposed in the active region defined by the deep trench DT. The deep trench DT may define a field region disposed between the active regions. The field insulating film 105 fills the deep trench DT.

Although one first lower pattern BP1 and one second lower pattern BP2 are shown as being disposed inside the active region defined by the deep trench DT, the present disclosure is not limited thereto. Two or more first lower patterns BP1 and second lower patterns BP2 may be disposed inside the active region.

In FIG. 34, the dummy protrusion pattern DFP may be disposed in a field region that distinguishes the active region. That is, a respective active region may be defined between the dummy protrusion patterns DFP adjacent to each other in the second direction D2.

The field insulating film 105 covers the upper surface of the dummy protrusion pattern DFP. The dummy protrusion pattern DFP includes the same material as the first lower pattern BP1 and the second lower pattern BP2. Unlike the shown example, two or more first lower patterns BP1 and second lower patterns BP2 may be disposed inside the active region.

The plurality of gate structures GS_1 and GS_2 do not include an inner gate structure.

The first source/drain pattern 150 is connected to the first fin channel pattern FP1. The first source/drain pattern 150 comes into contact with the first fin channel pattern FP1. The second source/drain pattern 250 is connected to the second fin channel pattern FP2. The second source/drain pattern 250 comes into contact with the second fin channel pattern FP2.

Side walls of the first source/drain recess 150R may be defined by the first fin channel pattern FP1. Although not shown, side walls of the second source/drain recesses (250R of FIG. 3) may be defined by the second fin channel pattern FP2.

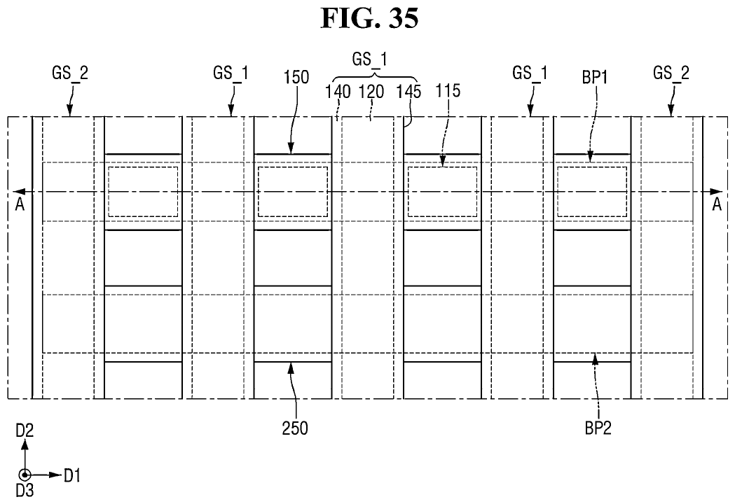

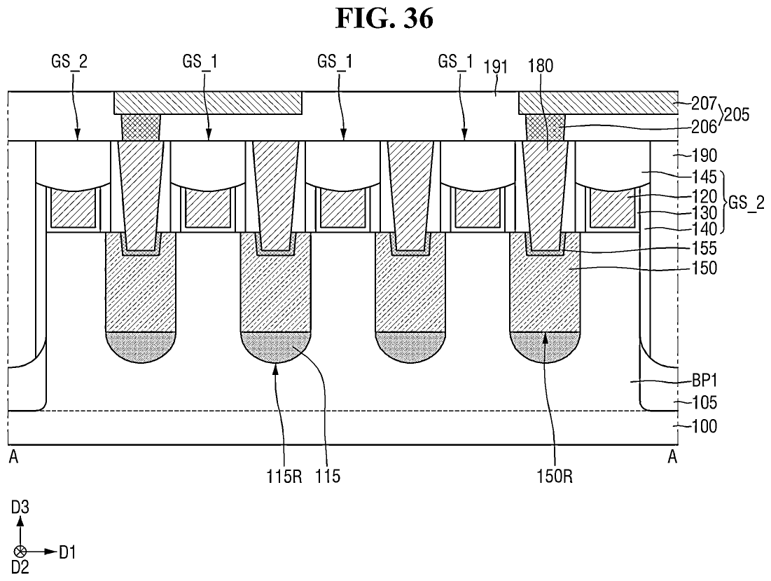

FIGS. 35 and 36 are diagrams for explaining a semiconductor device according to some embodiments. For convenience of explanation, the explanation will focus on points different from those explained using FIGS. 15 to 20.

For reference, FIG. 35 is a schematic plan view for explaining the semiconductor device according to some embodiments. FIG. 36 is a cross-sectional view taken along A-A of FIG. 35. Although not shown, as an example, a cross-sectional view taken along the second lower pattern BP2 in the first direction D1 may be similar to FIG. 36. As another example, a cross-sectional view taken along the second lower pattern BP2 in the first direction D1 may be similar to the shape except for the point blocking structure 115 in FIG. 36.

Referring to FIGS. 35 and 36, in the semiconductor devices according to some embodiments, the point blocking structure 115 may be disposed inside the first lower pattern BP1.

The blocking structure recess 115R may be formed inside the first lower pattern BP1.

The first source/drain recesses 150R may be defined by the first lower pattern BP1 and the point blocking structure 115. A bottom surface of the first source/drain recess 150R may be defined by the point blocking structure 115. The side walls of the first source/drain recess 150R may be defined by the first lower pattern BP1.

The first source/drain pattern 150 may come into contact with the first lower pattern BP1. The first source/drain pattern 150 may be included in the source/drain of a transistor that uses the first lower pattern BP1 as a channel region.

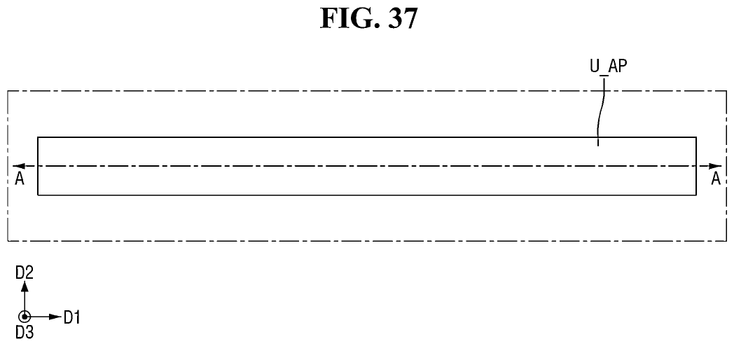

FIGS. 37 to 44 are intermediate step diagrams for describing a method for fabricating a semiconductor device according to some embodiments. A process of forming a component (for example, a first sheet pattern) on the first lower pattern BP1 will be described below. Accordingly, the process of forming the component on the second lower pattern BP2 may be understood. In addition, although not shown, a second line blocking structure (210 of FIG. 1) is formed on the second lower pattern (BP2 of FIG. 1) at the same time as the first line blocking structure 110 on the first lower pattern BP1.

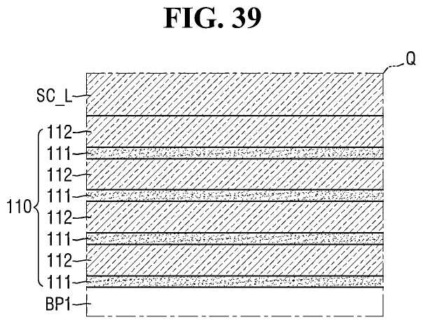

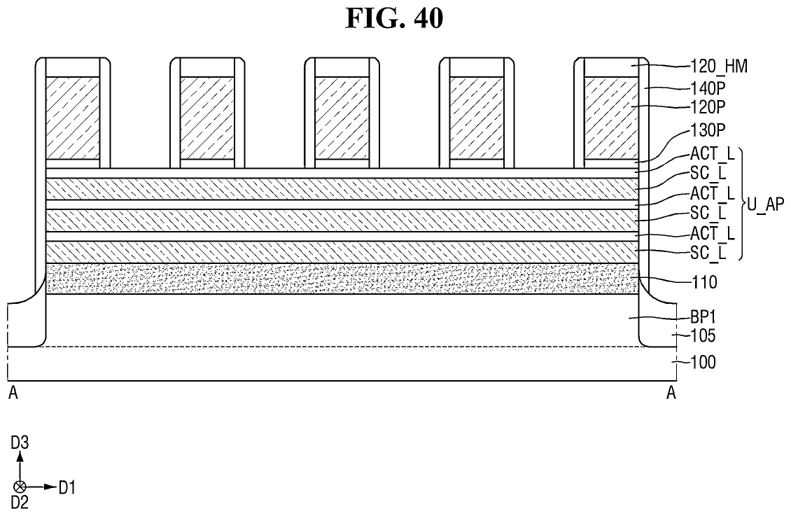

For reference, FIG. 38 is a cross-sectional view taken along line A-A of FIG. 37. FIG. 39 is an enlarged view of a portion Q of FIG. 38. FIGS. 40 to 44 are diagrams for explaining the fabricating processes performed after FIG. 38.

Referring to FIGS. 37 to 39, a first lower pattern BP1, a first line blocking structure 110, and an upper pattern structure U_AP may be formed on the substrate 100.

The first lower pattern BP1 extends in the first direction D1. The first line blocking structure 110 is disposed on the first lower pattern BP1. The first line blocking structure 110 is disposed between the first lower pattern BP1 and the upper pattern structure U_AP. The first line blocking structure 110 comes into contact with the first lower pattern BP1.

The first line blocking structure 110 may include a line blocking film 111 and a line insertion semiconductor film 112 alternately disposed on the first lower pattern BP1.

The upper pattern structure U_AP is disposed on the first line blocking structure 110. The upper pattern structure U_AP may come into contact with the first line blocking structure 110.

The upper pattern structure U_AP may include a plurality of sacrificial patterns SC_L and a plurality of active patterns ACT_L that are alternately stacked on the first line blocking structure 110. For example, the lowermost sacrificial pattern SC_L may come into contact with the first line blocking structure 110. In FIG. 39, the sacrificial pattern SC_L may come into contact with the line insertion semiconductor film 112. The sacrificial pattern SC_L may come into contact with the line blocking film 111, unlike the shown example.

For example, the active pattern ACT_L may include a silicon film. The sacrificial pattern SC_L may include a silicon-germanium film.

More specifically, a blocking structure film and an upper pattern film may be sequentially formed on the substrate 100. The blocking structure film and the upper pattern film may be patterned to form the first line blocking structure 110 and the upper pattern structure U_AP. A part of the substrate 100 may be etched to form the first lower pattern BP1. The blocking structure film may be formed on the substrate 100, using an epitaxial growth method.

Referring to FIG. 40, a plurality of dummy gate electrodes 120P extending in the second direction D2 are formed on the upper pattern structure U_AP.

A dummy gate insulating film 130P is formed between the dummy gate electrode 120P and the upper pattern structure U_AP. A dummy gate capping film 120_HM is disposed on the dummy gate electrode 120P. The dummy gate capping film 120_HM extends along the upper surface of the dummy gate electrode 120P.

The dummy gate insulating film 130P may include, for example, but not limited to, silicon oxide. The dummy gate electrode 120P may include, for example, but not limited to, polysilicon. The dummy gate capping film 120_HM may include, for example, but not limited to, silicon nitride.

Subsequently, a dummy gate spacer 140P is formed on the side walls of the dummy gate electrode 120P. The dummy gate spacer 140P is shown to cover single side wall of the upper pattern structure U_AP, but is not limited thereto. Unlike the shown example, the single side wall of the upper pattern structure U_AP may be covered with the dummy gate electrode 120P.

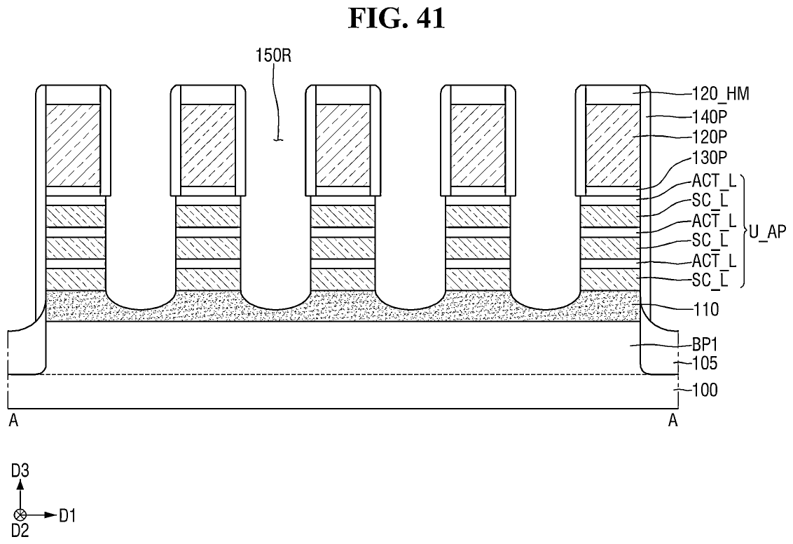

Referring to FIG. 41, a first source/drain recess 150R is formed inside (e.g., extending into) the upper pattern structure U_AP and the first line blocking structure 110, using the dummy gate electrode 120P as a mask.

A bottom surface of the first source/drain recess 150R may be defined by the first line blocking structure 110.

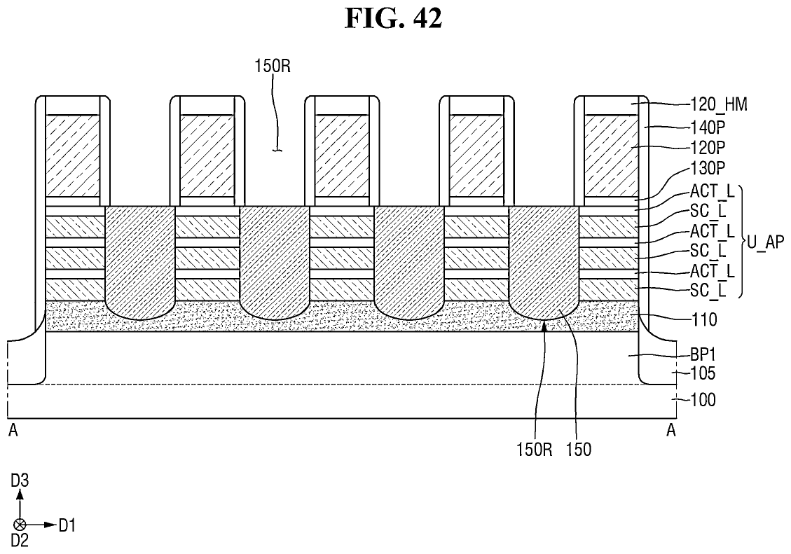

Referring to FIG. 42, the first source/drain pattern 150 is formed on the first line blocking structure 110.

The first source/drain pattern 150 fills the first source/drain recesses 150R. The first source/drain pattern 150 is formed between the dummy gate electrodes 120P adjacent to each other in the first direction D1. The first source/drain pattern 150 is connected to the active pattern ACT_L. The first source/drain pattern 150 may come into contact with the first line blocking structure 110.

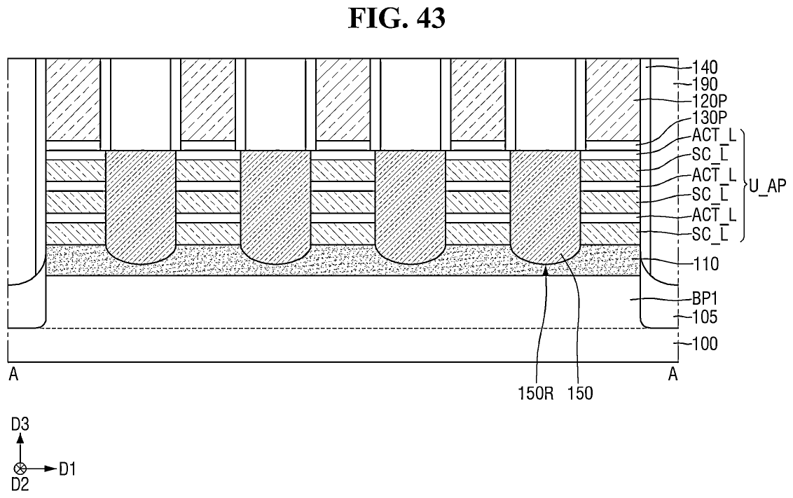

Referring to FIG. 43, the first interlayer insulating film 190 is formed on the first source/drain pattern 150.

Subsequently, a part of the first interlayer insulating film 190 and the dummy gate capping film 120_HM are removed to expose the upper surface of the dummy gate electrode 120P. The gate spacer 140 may be formed, while the upper surface of the dummy gate electrode 120P is being exposed.

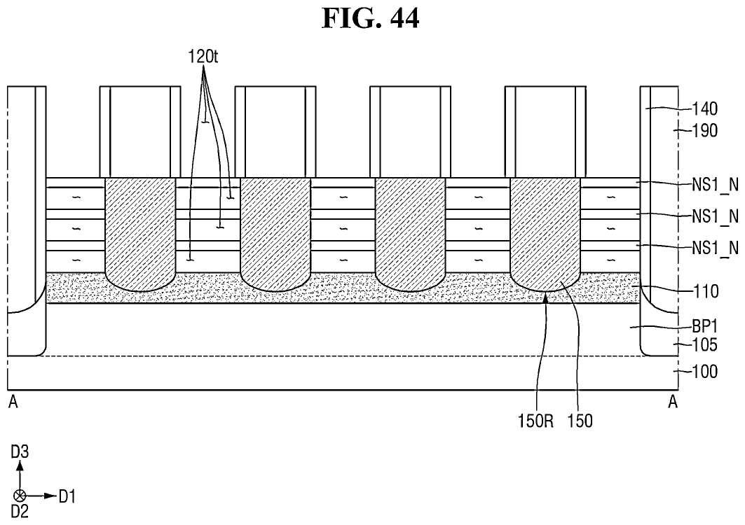

Referring to FIG. 44, the upper pattern structure U_AP between the gate spacers 140 may be exposed by removing the dummy gate insulating film 130P and the dummy gate electrode 120P.

After that, the sacrificial pattern SC_L may be removed to form the first sheet pattern NS1. As a result, a gate trench 120t is formed between the gate spacers 140. Also, the first sheet pattern NS1 connected to the first source/drain pattern 150 is formed.

Next, referring to FIG. 2, a gate insulating film 130 and a gate electrode 120 may be formed inside the gate trench 120t. Further, the gate capping pattern 145 may be formed.

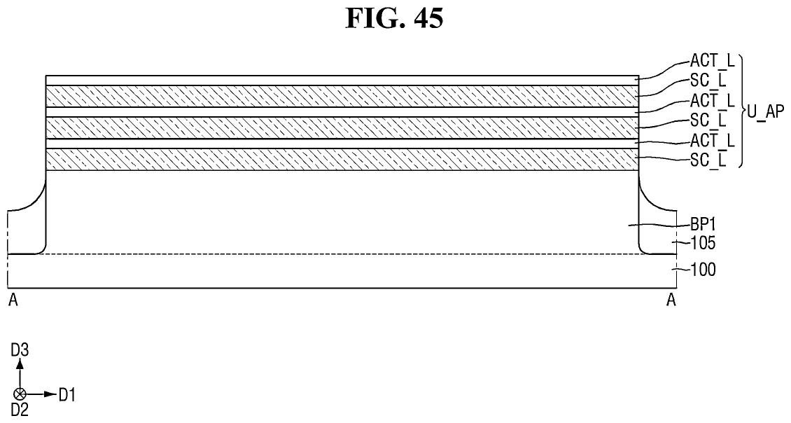

FIGS. 45 to 49 are intermediate step diagrams for describing a method for fabricating the semiconductor device according to some embodiments. For convenience of explanation, the explanation will focus on points that are different from those explained using FIGS. 37 to 44.

Referring to FIG. 45, a first lower pattern BP1 and an upper pattern structure U_AP may be formed on the substrate 100.

The upper pattern structure U_AP is formed on the first lower pattern BP1. The upper pattern structure U_AP may come into contact with the first lower pattern BP1.

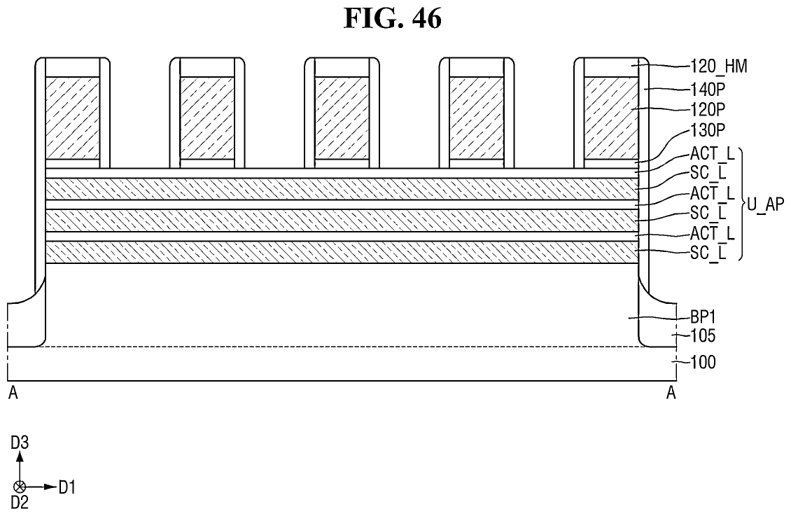

Referring to FIG. 46, a plurality of dummy gate electrodes 120P extending in the second direction D2 are formed on the upper pattern structure U_AP.

The dummy gate insulating film 130P and the dummy gate capping film 120_HM are formed on the upper pattern structure U_AP. Subsequently, the dummy gate spacer 140P is formed on the side walls of the dummy gate electrode 120P.

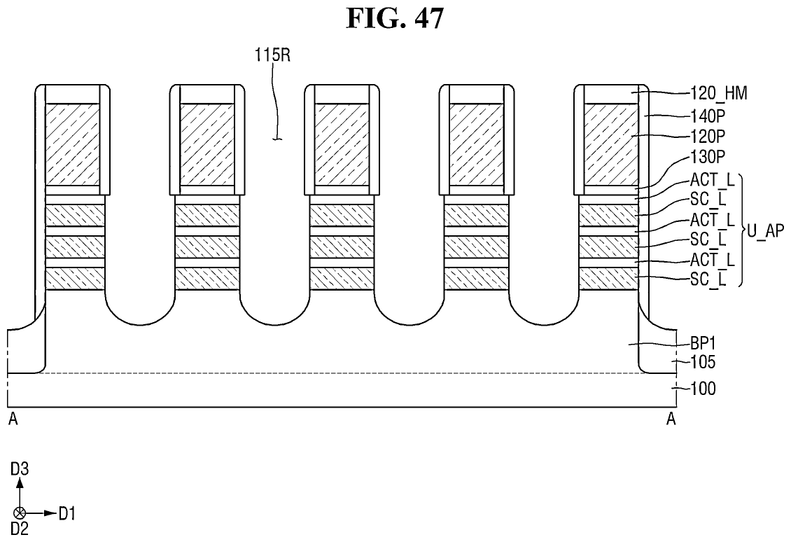

Referring to FIG. 47, a blocking structure recess 115R is formed inside (e.g., extending into) the upper pattern structure U_AP and the first lower pattern BP1, using the dummy gate electrode 120P as a mask.

A bottom surface of the blocking structure recess 115R may be defined by the first lower pattern BP1.

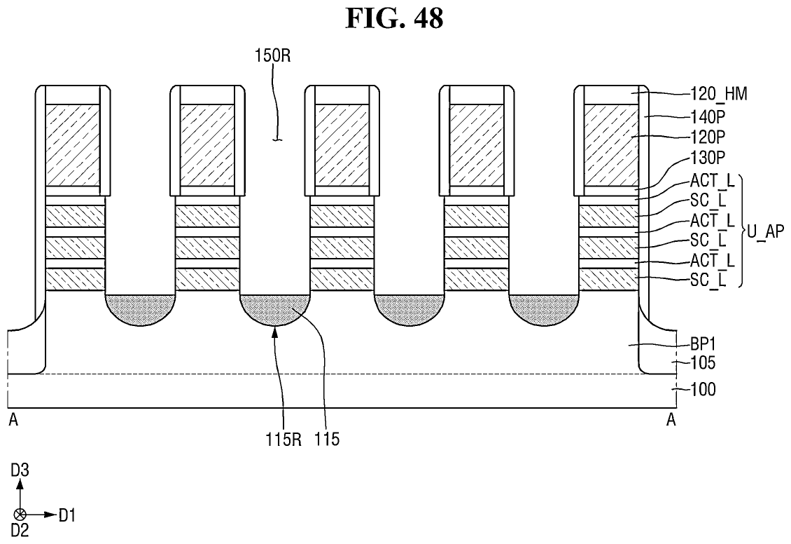

Referring to FIG. 48, the point blocking structure 115 is formed inside the blocking structure recess 115R.

The point blocking structure 115 may fill a part of the blocking structure recess 115R. The point blocking structure 115 may come into contact with the first lower pattern BP1. The point blocking structure 115 is not connected with the active pattern ACT_L of the upper pattern structure U_AP.

The point blocking structure 115 is formed on the first lower pattern BP1, and the first source/drain recess 150 may be formed on the point blocking structure 115. In other words, the first source/drain recess 150 may be a remaining portion or the rest of the blocking structure recess 115R.

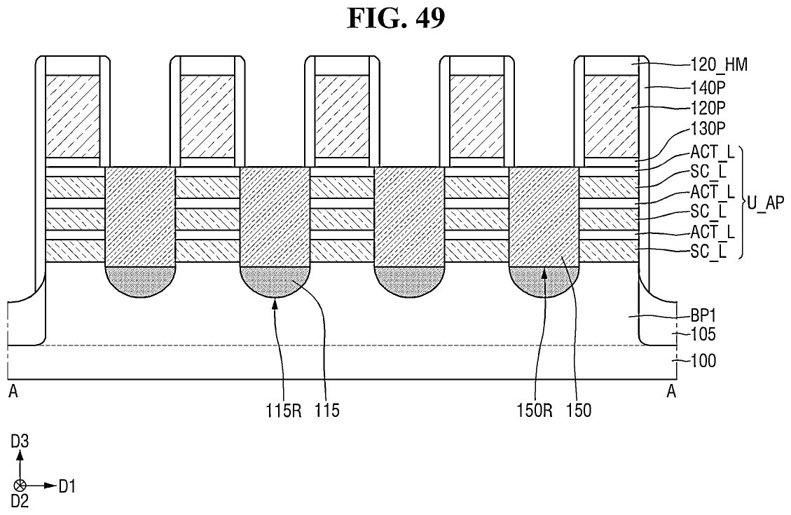

Referring to FIG. 49, the first source/drain pattern 150 is formed on the point blocking structure 115.

The first source/drain pattern 150 may come into contact with the point blocking structure 115. The first source/drain pattern 150 is connected to the active pattern ACT_L on the point blocking structure 115. The point blocking structure 115 may be formed on the first lower pattern BP1, using an epitaxial growth method.

Next, referring to FIG. 43, a first interlayer insulating film 190 is formed on the first source/drain pattern 150. Also, a gate spacer 140 is formed on the side wall of the dummy gate electrode 120P.

Referring to FIG. 44, the dummy gate insulating film 130P, the dummy gate electrode 120P and the sacrificial pattern SC_L are sequentially removed to form the first sheet pattern NS1 connected to the first source/drain pattern 150. A gate insulating film 130, a gate electrode 120, gate capping pattern 145, etc., may be formed to provide a structure similar to FIG. 16.

In concluding the detailed description, those skilled in the art will appreciate that many variations and modifications may be made to the disclosed embodiments without substantially departing from the principles of the present inventive concept. Therefore, the disclosed embodiments of the invention are provided in a generic and descriptive sense only and not for purposes of limitation.

1. A semiconductor device comprising:
a lower pattern extending in a first direction;
a first blocking structure on the lower pattern and comprising at least one first blocking film, the first blocking film comprising an oxygen-doped crystalline silicon film;
a source/drain pattern on the first blocking structure; and
a gate structure extending in a second direction on the lower pattern and comprising a gate electrode and a gate insulating film.

2. The semiconductor device of claim 1,
wherein the first blocking structure extends in the first direction along an upper surface of the lower pattern, and
the first blocking structure overlaps the gate structure in a third direction that is different from the first and second directions.

3. The semiconductor device of claim 2,
wherein a thickness of the first blocking structure at a portion thereof overlapping the gate structure in the third direction is greater than a height from the upper surface of the lower pattern to a lowermost part of the source/drain pattern.

4. The semiconductor device of claim 1,
wherein the lower pattern comprises a blocking structure recess,
the first blocking structure is in the blocking structure recess, and
the first blocking structure does not overlap the gate electrode in a third direction that is different from the first and second directions.

5. The semiconductor device of claim 4,
wherein the at least one first blocking film comprises opposing surfaces that are substantially planar in a cross-sectional view.

6. The semiconductor device of claim 4,
wherein the at least one first blocking film has a curved surface shape that protrudes toward a bottom of the blocking structure recess in a cross-sectional view.

7. The semiconductor device of claim 4, wherein the oxygen-doped crystalline silicon film is a first oxygen-doped crystalline silicon film, and further comprising:
a second blocking structure that is on an upper surface of the lower pattern and overlaps the gate structure in the third direction,
wherein the second blocking structure comprises at least one second blocking film, and
the second blocking film comprises a second oxygen-doped crystalline silicon film.

8. The semiconductor device of claim 1, wherein the at least one first blocking film comprises a plurality of first blocking films,
wherein the first blocking structure comprises a plurality of the first blocking films and one or more first insertion semiconductor films,
the one or more first insertion semiconductors films comprise a crystalline silicon film having a lower oxygen concentration than the first blocking films, and
the first blocking films and the first insertion semiconductor films are alternately stacked.

9. The semiconductor device of claim 8,
wherein the first blocking films comprise a first sub-blocking film and a second sub-blocking film that are spaced apart in a third direction that is different from the first and second directions, and
a thickness of the first sub-blocking film is different from a thickness of the second sub-blocking film.

10. The semiconductor device of claim 8,
wherein the first blocking films comprise a first sub-blocking film and a second sub-blocking film that are spaced apart in a third direction that is different from the first and second directions, and
a concentration of oxygen in the first sub-blocking film is different from a concentration of oxygen in the second sub-blocking film.

11. The semiconductor device of claim 1, further comprising:
a plurality of sheet patterns spaced apart from the lower pattern in a third direction that is different from the first and second directions,
wherein the gate structure comprises an inner gate structure between the lower pattern and the sheet patterns and between ones of the sheet patterns, and the inner gate structure comprises the gate electrode and the gate insulating film.

12. The semiconductor device of claim 11,
wherein the source/drain pattern contacts the gate insulating film of the inner gate structure.

13. The semiconductor device of claim 11,
wherein the gate structure further comprises an inner spacer between the inner gate structure and the source/drain pattern.

14. A semiconductor device comprising:
a lower pattern extending in a first direction;
a blocking structure on the lower pattern and comprising at least one blocking film, the at least one blocking film comprising an oxygen-doped crystalline silicon film;
a plurality of sheet patterns on the blocking structure and arranged in a second direction;
a gate structure extending in a third direction on the lower pattern and comprising a gate electrode and a gate insulating film, the gate electrode overlapping the blocking structure in the second direction; and
a source/drain pattern that overlaps the blocking structure in the second direction and is connected to the sheet pattern.

15. The semiconductor device of claim 14,
wherein the at least one blocking film comprises a first sub-blocking film extending along an upper surface of the lower pattern, and
the first sub-blocking film overlaps the source/drain pattern and the gate structure in the second direction.

16. The semiconductor device of claim 15,
wherein the at least one blocking film further comprises a second sub-blocking film on the first sub-blocking film, and
a height from the upper surface of the lower pattern to the second sub-blocking film is greater than a height from the upper surface of the lower pattern to a lowermost part of the source/drain pattern.

17. The semiconductor device of claim 14,
wherein the blocking structure comprises a first blocking structure and a second blocking structure,
the first blocking structure comprises at least one first blocking film,
the second blocking structure comprises at least one second blocking film,
the at least one first blocking film and the at least one second blocking film comprise a first oxygen-doped crystalline silicon film and a second oxygen-doped crystalline silicon film, respectively, and
the first blocking structure overlaps the source/drain pattern in the second direction and does not overlap the gate electrode in the second direction.

18. The semiconductor device of claim 17,
wherein the first blocking structure is on the second blocking structure.

19. A semiconductor device comprising:
a lower pattern that extends in a first direction and comprises a blocking structure recess;
a blocking structure on the lower pattern and comprising a plurality of blocking films and one or more insertion semiconductor films, the blocking films comprising an oxygen-doped crystalline silicon film, and the insertion semiconductor films comprising a crystalline silicon film having a lower oxygen concentration than the blocking films;
a plurality of sheet patterns on the lower pattern and arranged in a second direction;
a source/drain pattern connected to the sheet pattern on the blocking structure and comprising n-type dopants; and
a gate structure extending in a third direction on the lower pattern and comprising a gate electrode and a gate insulating film.

20. (canceled)

21. The semiconductor device of claim 19,
wherein the plurality of blocking films do not overlap the gate electrode in the second direction.

22.-24. (canceled)
